(19) United States
(12) Patent Application Publication
(10) Pub. No.: US 2023/0238410 A1
(43) Pub. Date: Jul. 27, 2023

(54) SURFACE GRATING IN PHOTODETECTOR DEVICE

(71) Applicant: TEXAS INSTRUMENTS INCORPORATED, Dallas, TX (US)

(72) Inventors: Henry Edwards, Garland, TX (US); Rahmi Hezar, Allen, TX (US); Udumbara Wijesinghe, Richardson, TX (US); Wenjuan Fan, Allen, TX (US); Gerd Schuppener, Allen, TX (US)

(21) Appl. No.: 17/586,001

(22) Filed: Jan. 27, 2022

(51) Int. Cl. H01L 27/146

(52) U.S. Cl. CPC H01L 27/14623; H01L 27/14643; H01L 27/1463; H01L 27/14685

(57) ABSTRACT

The present disclosure generally relates to a surface grating in a photodetector device. In an example, a semiconductor device structure includes a photodetector device. The photodetector device includes one or more photodiodes disposed in or over a semiconductor substrate, and includes a surface grating disposed at a respective surface of each photodiode of the one or more photodiodes. The surface grating has one or more periodicities. Each periodicity of the one or more periodicities has a period that is along a direction parallel to a first lateral direction across the semiconductor substrate and that is equal to or less than half of a dimension of at least one photodiode of the one or more photodiodes along a direction parallel to the first lateral direction. The one or more periodicities includes multiple different pitches.

### BACKGROUND

A photodiode in a semiconductor device may receive incident electromagnetic radiation (e.g., light) and convert the electromagnetic radiation into an electrical current. A type of photodiodes includes an avalanche photodiode (APD). APDs are being implemented in direct time of flight applications, such as light detection and ranging (LiDAR) and augmented-reality/virtual-reality (AR/VR), due to increased responsivity to electromagnetic radiation as a result of an avalanche process that can provide a linear current gain. Integration of the APD with signal conditioning circuitry, such as a transimpedance amplifier (TIA), may provide some advantages in cost and performance. When integrating circuitry in a photodetector device that includes a photodiode, challenges may occur that may result in signal loss at the photodiode.

### SUMMARY

An example described herein is a semiconductor device structure. The semiconductor device structure includes a photodetector device. The photodetector device includes one or more photodiodes disposed in or over a semiconductor substrate, and includes a surface grating disposed at a respective surface of each photodiode of the one or more photodiodes. The surface grating has one or more periodicities. Each periodicity of the one or more periodicities has a period that is along a direction parallel to a first lateral direction across the semiconductor substrate and that is equal to or less than half of a dimension of at least one photodiode of the one or more photodiodes along a direction parallel to the first lateral direction. The one or more periodicities includes multiple different pitches.

Another example described herein is a semiconductor device structure. The semiconductor device structure includes a photodetector device. The photodetector device includes a first sub-pixel photodiode disposed in or over a semiconductor substrate and a second sub-pixel photodiode disposed in or over the semiconductor substrate. The first sub-pixel photodiode being electrically connected in parallel with the second sub-pixel photodiode. The photodetector device further includes a surface grating. The surface grating includes a first sub-pixel surface grating disposed at a surface of the first sub-pixel photodiode and a second sub-pixel surface grating disposed at a surface of the second sub-pixel photodiode. A configuration of the first sub-pixel surface grating being different from a configuration of the second sub-pixel surface grating.

A further example described herein is a method for semiconductor processing. The method includes forming one or more photodiodes of a photodetector device and forming a surface grating disposed at a respective surface of each photodiode of the one or more photodiodes. The one or more photodiodes are formed disposed in or over a semiconductor substrate. The surface grating has one or more periodicities. Each periodicity of the one or more periodicities has a period that is along a direction parallel to a lateral direction across the semiconductor substrate and that is equal to or less than half of a dimension of at least one photodiode of the one or more photodiodes along a direction parallel to the lateral direction. The one or more periodicities include multiple different pitches.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a plan view generally illustrating a structure having single pitch periodicity to illustrate aspects of pitch and periodicity according to some examples.

FIG. 2 is a plan view generally illustrating a structure having multiple pitch periodicity to illustrate aspects of pitch and periodicity according to some examples.

FIG. 3 is a plan view of a photodetector device according to some examples.

FIG. 4 is a cross-section view of a semiconductor device structure of the photodetector device of FIG. 3 according to some examples.

FIGS. 5 and 6 are plan views of sub-pixel antireflective surface gratings according to some examples.

FIG. 7 is a cross-section view of a semiconductor device structure including the sub-pixel antireflective surface grating of FIG. 5 or 6 according to some examples.

FIGS. 8 and 9 are plan views of sub-pixel antireflective surface gratings according to some examples.

FIG. 10 is a cross-section view of a semiconductor device structure including the sub-pixel antireflective surface grating of FIG. 8 or 9 according to some examples.

FIGS. 11 and 12 are plan views of sub-pixel antireflective surface gratings according to some examples.

FIG. 13 is a cross-section view of a semiconductor device structure including the sub-pixel antireflective surface grating of FIG. 11 or 12 according to some examples.

FIGS. 14 and 15 are plan views of sub-pixel antireflective surface gratings according to some examples.

FIG. 16 is a cross-section view of a semiconductor device structure including the sub-pixel antireflective surface grating of FIG. 14 or 15 according to some examples.

FIGS. 17 and 18 are plan views of sub-pixel antireflective surface gratings according to some examples.

FIG. 19 is a cross-section view of a semiconductor device structure including the sub-pixel antireflective surface grating of FIG. 17 or 18 according to some examples.

FIGS. 20 and 21 are plan views of sub-pixel antireflective surface gratings according to some examples.

FIG. 22 is a cross-section view of a semiconductor device structure including the sub-pixel antireflective surface grating of FIG. 20 or 21 according to some examples.

FIGS. 23 and 24 are plan views of sub-pixel antireflective surface gratings according to some examples.

FIG. 25 is a cross-section view of a semiconductor device structure including the sub-pixel antireflective surface grating of FIG. 23 or 24 according to some examples.

FIG. 26 is a plan view of a sub-pixel antireflective surface grating according to some examples.

FIG. 27 is a cross-section view of a semiconductor device structure including the sub-pixel antireflective surface grating of FIG. 26 according to some examples.

FIG. 28 is a layout of respective portions of generalized sub-pixel antireflective surface gratings according to some examples.

FIG. 29 is a layout of respective portions of generalized sub-pixel antireflective surface gratings according to some examples.

FIG. 30 is a layout of respective portions of generalized sub-pixel antireflective surface gratings according to some examples.

FIG. 31 is a layout of respective portions of generalized sub-pixel antireflective surface gratings according to some examples.

FIG. 32 is a plan view of an antireflective surface grating according to some examples.

FIG. 33 is a plan view of an antireflective surface grating according to some examples.

FIG. 34 is a plan view of an antireflective surface grating according to some examples.

FIG. 35 is a plan view of an antireflective surface grating according to some examples.

FIG. 36 is a method for semiconductor processing to form a photodetector device according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

In some photodetector devices, electromagnetic radiation (e.g., light) passing into the photodetector device can become incident on layers of different materials. These layers of different materials can form an etalon. The etalon can create coherent interference in the electromagnetic radiation signal that the photodetector device detects. The coherent interference resulting from the etalon can create oscillations in the electromagnetic radiation signal that are a function of the wavelength of the electromagnetic radiation signal.

According to some examples, an antireflective surface grating can be formed in the photodetector device to break up at least some symmetry in the layers or materials that would otherwise form an etalon in the photodetector device. Although creating an antireflective surface grating has been observed to reduce symmetry and reduce coherent interference, the antireflective surface grating can have a single pitch periodicity across the photodetector device that may create some coherent interference in the electromagnetic radiation signal. Generally, as explained by the grating equation, an antireflective surface grating can result in multiple rays of electromagnetic radiation (from electromagnetic radiation that is incident on the antireflective surface grating) being transmitted through the antireflective surface grating. When the antireflective surface grating has a single pitch periodicity, the transmitted rays of electromagnetic radiation generally have same fixed angles of refraction that can lead to significant coherent interference as a function of the angle of incidence and wavelength of the electromagnetic radiation incident on the antireflective surface grating.

Some examples described herein provide for antireflective surface gratings that may reduce coherent interference across angles of incidence and wavelengths of the electromagnetic radiation. An antireflective surface grating according to some examples can introduce multiple different angles of refraction, according to the grating equation, due to, for example, differences in pitches in one or more periodicity or changes in configurations of the antireflective surface grating. The different angles of refraction of the transmitted electromagnetic radiation can reduce the magnitude of oscillations that are a function of the angle of incidence and wavelength of the electromagnetic radiation signal.

A photodetector device can have one or multiple pixels that each sense electromagnetic radiation at a respective location. In some examples, a pixel can have multiple photodiodes that are electrically connected together (e.g., in parallel) that together sense electromagnetic radiation for that pixel (referred to as “sub-pixel photodiodes” for ease). In some examples, a pixel can have a single photodiode that senses electromagnetic radiation for that pixel (referred to as a “single pixel photodiode” for ease).

For sub-pixel photodiodes of a given pixel, a pixel antireflective surface grating of the respective pixel may comprise sub-pixel antireflective surface gratings disposed at respective surfaces of the sub-pixel photodiodes. In some examples, a first sub-pixel antireflective surface grating has a different configuration than a configuration of a second sub-pixel antireflective surface grating. In some of these examples, the configurations of the first and second sub-pixel antireflective surface gratings may have no general correspondence between physical features of the sub-pixel antireflective surface gratings. In some examples, the configurations of the first and second sub-pixel antireflective surface gratings may generally correspond with each other, except with one or more differences between corresponding physical features of the different sub-pixel antireflective surface gratings.

Any sub-pixel antireflective surface grating may individually have a periodicity along one or both of two perpendicular lateral directions across the respective surface of that sub-pixel photodiode. A structure has periodicity when the structure has a repeating period. A periodicity of a sub-pixel antireflective surface grating may have a period along a lateral direction that is a length of one pitch in the sub-pixel antireflective surface grating (e.g., single pitch periodicity) or that is a cumulative length of multiple different pitches in the sub-pixel antireflective surface grating (e.g., multiple pitch periodicity). Neighboring physical features of a same type aligned along an axis or direction in a structure can have a pitch between corresponding lateral boundaries of the respective neighboring physical features. A pitch has a length and includes physical feature(s) and/or interval(s) therebetween. For clarity a period of any periodicity of a sub-pixel antireflective surface grating is equal to or less than half of a lateral dimension of a photodiode (e.g., the respective sub-pixel photodiode, which may be laterally defined by isolation regions) along the direction of the periodicity.

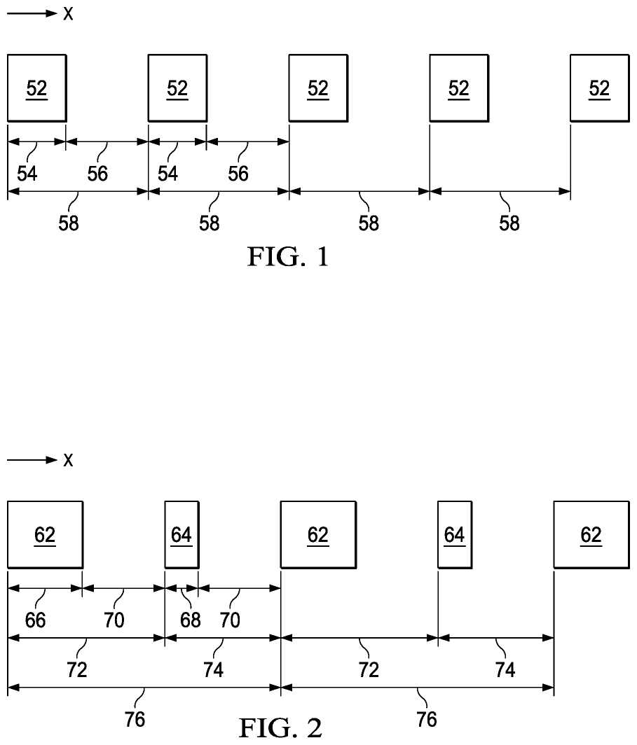

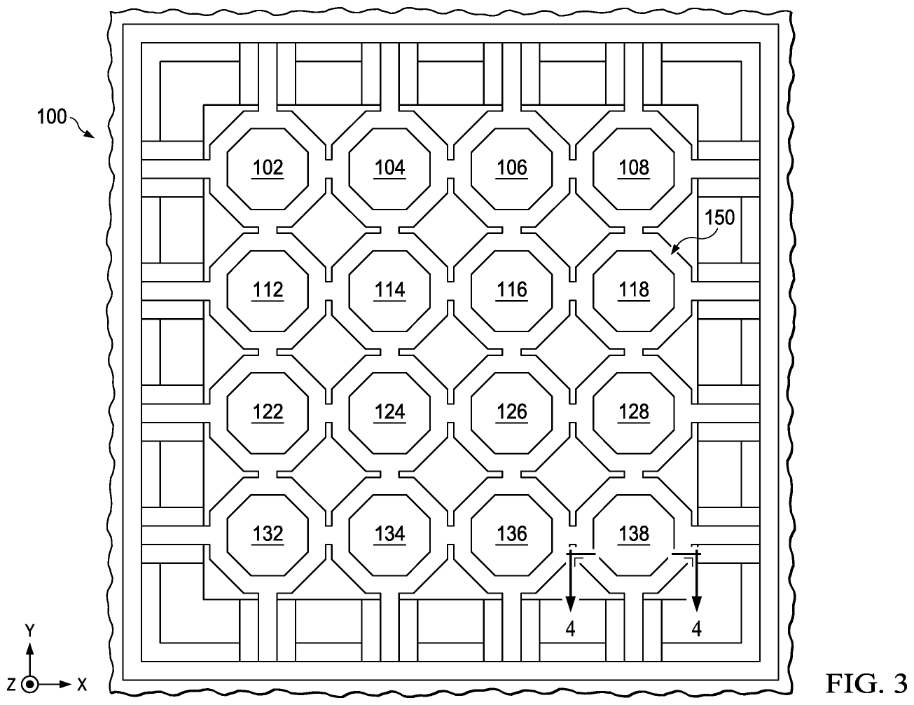

FIGS. 1 and 2 generally illustrates structures having single pitch periodicity and multiple pitch periodicity, respectively, to illustrate aspects of pitch and periodicity. In FIG. 1, physical features 52 of a same type are aligned along a direction parallel to an x-direction. Each physical feature 52 has a same dimension 54, and each neighboring pair of physical features 52 has a distance 56 between neighboring lateral boundaries of the respective neighboring physical features 52. Hence, the structure of FIG. 1 has a single pitch, and a length of that pitch is equal to a period that is repeated within the structure. Hence, the structure of FIG. 1 has a single pitch periodicity.

In FIG. 2, physical features 62, 64 of a same type are aligned along a direction parallel to an x-direction, and are disposed alternatingly in that alignment. The physical features 62 have a dimension 66, and physical features 64 have a dimension 68 that is not equal to the dimension 66. Each neighboring pair of physical features 62, 64 has a distance 70 between neighboring lateral boundaries of the respective neighboring physical features 62, 64. Due to the differing dimensions 66, 68, in this illustration, the structure has different pitches 72, 74. Respective lengths of pitch 72 and pitch 74 cumulatively form a period 76, and the period 76 repeats within the structure. Hence, the structure of FIG. 2 has a multiple pitch periodicity.

In some examples where configurations of first and second sub-pixel antireflective surface gratings differ, the first and second sub-pixel antireflective surface gratings can each have a single pitch periodicity along directions parallel to a same lateral direction, and the respective pitches that result in the single pitch periodicities of the first and second sub-pixel antireflective surface gratings differ. Also, in some examples where configurations of first and second sub-pixel antireflective surface gratings differ, the first and second sub-pixel antireflective surface gratings can each have a multiple pitch periodicity along directions parallel to a same lateral direction, and at least one pitch of the first sub-pixel antireflective surface grating differs from at least one pitch of the second sub-pixel antireflective surface grating. Whether in single pitch periodicities or in a multiple pitch periodicity, at least two of the differing pitches are non-harmonic (e.g., the dimension(s) and distance(s) of a pitches are not a same integer multiple of respective dimension(s) and distance(s) of another pitches). These aspects may be carried out in respective directions parallel to two perpendicular lateral directions.

In some examples, a first sub-pixel antireflective surface grating has a same configuration as a configuration of a second sub-pixel antireflective surface grating. In such examples, the first and second sub-pixel antireflective surface gratings can each have a same multiple pitch periodicity along directions parallel to a same lateral direction. Like above, at least two of the differing pitches of the multiple pitch periodicity are non-harmonic. This aspect may be carried out in respective directions parallel to two perpendicular lateral directions. In other examples where configurations of first and second sub-pixel antireflective surface gratings are the same, physical features of the first and second sub-pixel antireflective surface gratings can be randomly located within the respective antireflective surface grating such that no periodicity occurs. Other configurations where no periodicity is created in the first and second sub-pixel antireflective surface gratings can be implemented.

For a single pixel photodiode and for any sub-pixel photodiode, the single pixel or sub-pixel antireflective surface grating at the surface of that photodiode can have a multiple pitch periodicity along directions parallel to a lateral direction. Like above, at least two of the differing pitches of the multiple pitch periodicity are non-harmonic. This aspect may be carried out in respective directions parallel to two perpendicular later directions. In other single pixel photodiode or a sub-pixel photodiode examples, physical features of the antireflective surface gratings can be randomly located within the antireflective surface grating such that no periodicity occurs in the antireflective surface grating. Other configurations where no periodicity is created in the antireflective surface grating can be implemented.

As detailed in examples described below, pitches may differ in many ways. Pitches can differ by any manner where physical feature(s) and/or interval(s) therebetween of one pitch is changed relative to another pitch. Pitches may differ by having different types of physical features within the pitches. Pitches may differ by having different lengths of the pitches. Pitches may differ by having different dimensions of corresponding physical features of a same type in the pitches. Pitches may differ by having different distances between corresponding neighboring pairs of physical features of a same type in the pitches.

The foregoing examples, broadly described, can introduce multiple pitches or randomness in an antireflective surface grating across a pixel comprising one or more photodiodes. Generally, the antireflective surface grating, collectively across the one or more photodiodes, does not have a single pitch periodicity in at least one lateral direction across the one or more photodiodes. More particularly, the antireflective surface grating, collectively across the one or more photodiodes, may not have a single pitch periodicity in either of two perpendicular lateral directions across the one or more photodiodes. The multiple pitches or randomness of the antireflective surface grating can introduce more solutions of transmitted electromagnetic radiation according to the grating equation into the photodiode(s). In doing so, the magnitude of oscillations of a signal output by a pixel of the photodetector device, which oscillations are a function of the angle of incidence and wavelength of the electromagnetic radiation signal, can be reduced. Many variations and/or permutations of the broadly described examples above and of the particular examples described below may be implemented.

FIG. 3 is a plan view of a photodetector device 100 according to some examples. FIG. 3 and subsequent figures include a three axis coordinate reference (X-Y-Z) to aid in orienting the depicted examples. The plan view of FIG. 3 is in an x-y plane.

The photodetector device 100 includes sub-pixel regions 102, 104, 106, 108, 112, 114, 116, 118, 122, 124, 126, 128, 132, 134, 136, 138. Each sub-pixel region 102-138 includes a sub-pixel photodiode in or over a substrate, which photodiode may include a p-n junction. The sub-pixel regions 102-138 in the illustrated example are arranged in an array (e.g., a 4×4 array comprising sixteen sub-pixel regions). In other examples, the sub-pixel regions 102-138 can be arranged in another arrangement, and the photodetector device 100 can comprise any number of sub-pixel regions. The sub-pixel regions 102-138 are octagonal in the plan view of the illustrated example, and may be any other geometric shape (e.g., polygonal shape) in other examples.

The photodetector device 100 includes a metallization region 150. The metallization region 150 includes regions laterally (e.g., in an x-direction and/or y-direction in the illustration) outside of the sub-pixel regions 102-138. Metal patterns (e.g., metal lines and/or vias) can be disposed in and routed through dielectric layers in the metallization region 150. Metal patterns are generally not disposed in the sub-pixel regions 102-138 (e.g., except to electrically connect to photodiodes). The sub-pixel photodiodes of the sub-pixel regions 102-138 are electrically connected together, e.g., through metal patterns in the metallization region 150. The sub-pixel photodiodes of the sub-pixel regions 102-138 are electrically connected together in parallel in some examples. Additionally, devices, such as transistors, diodes, etc., may be disposed in and/or over the substrate in the metallization region 150.

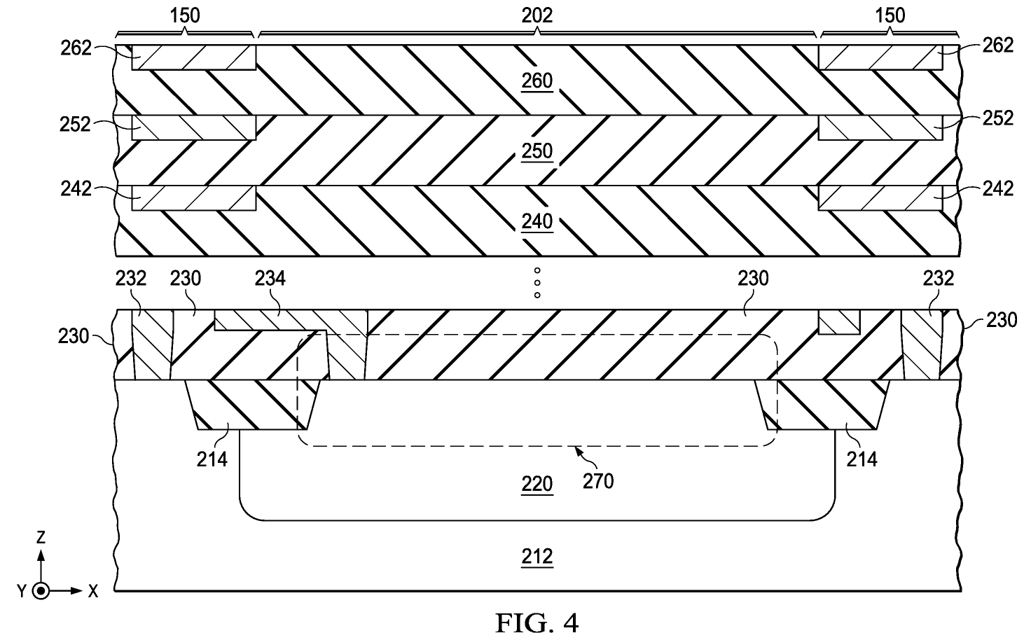

FIG. 4 illustrates a cross-section 4 in an x-direction through the sub-pixel region 138 in FIG. 3 according to some examples. The cross-section 4 is in an x-z plane. A similar cross-section may be in a y-z plane. Additionally, the cross-section 4 of FIG. 4 is generally illustrative of each of the sub-pixel regions 102-138 of FIG. 3. The cross-section of FIG. 4 shows the metallization region 150 and a sub-pixel region 202.

The photodetector device 100 includes a semiconductor substrate 212. The semiconductor substrate 212 can be or include a bulk semiconductor material, a semiconductor-on-insulator (SOI), or any other appropriate semiconductor substrate, and the semiconductor material of the semiconductor substrate 212 can be or include silicon (Si), silicon carbide (SiC), silicon germanium (SiGe), gallium nitride (GaN), gallium arsenide (GaAs), the like, or a combination thereof. Additionally, the semiconductor substrate 212 can include epitaxially grown semiconductor layers of the same, similar, or dissimilar semiconductor material, e.g., on or over a bulk substrate. The epitaxial layer(s) can be doped (e.g., by in-situ doping) during growth to form a p-n junction for photo-sensing in some examples. In some examples, the semiconductor substrate 212 includes a silicon substrate, which may be singulated from a bulk silicon wafer at the conclusion of semiconductor processing.

Isolation regions 214 are depicted disposed in the semiconductor substrate 212 in the metallization region 150. In other areas of the metallization region 150, various devices (e.g., transistors) can be disposed in and/or over the semiconductor substrate 212. Each isolation region 214 extends at least from a major surface (e.g., on and/or in which devices are formed) of the semiconductor substrate 212 to some depth in the semiconductor substrate 212. The isolation regions 214 can be shallow trench isolations (STIs), deep trench isolations (DTIs), local oxidation of semiconductor (LOCOS), or the like. Each isolation region 214 includes a dielectric material, such as an oxide, a nitride, the like, or a combination thereof.

A sub-pixel photodiode is disposed in or over the semiconductor substrate 212. A cathode region 220 is disposed in or over the semiconductor substrate 212. The cathode region 220 is disposed laterally between the isolation regions 214. In some examples, the semiconductor substrate 212 is doped with a p-type dopant (such as boron). Further, in such examples, the cathode region 220 is doped with an n-type dopant (such as phosphorus or arsenic). The cathode region 220 may form the cathode of the sub-pixel photodiode, and the semiconductor substrate 212 may form the anode of the sub-pixel photodiode. Hence, in such examples, the cathode and anode form a p-n junction of the sub-pixel photodiode. The p-n junction is configured to sense electromagnetic radiation (e.g., light) incident on the semiconductor substrate 212 in the sub-pixel region 202. In some examples, although not explicitly shown, the semiconductor substrate 212 may be doped with an n-type dopant and the region 220 may be doped with a p-type dopant, such that the region 220 operates as the anode and the semiconductor substrate 212 operates as the cathode.

A first dielectric layer 230 is disposed on or over the semiconductor substrate 212. The first dielectric layer 230 can include multiple dielectric layers, such as an etch stop layer (e.g., silicon nitride (SiN) or the like) disposed conformally along exposed top and sidewall surfaces and an inter-layer dielectric (e.g., an oxide or the like) disposed on the etch stop layer. Metal patterns (e.g., metal lines, contacts, and/or vias), including anode contacts 232 and cathode contact 234, are disposed in the first dielectric layer 230 in the metallization region 150. The anode contacts 232 are disposed through the first dielectric layer 230 and electrically contact the semiconductor substrate 212 (e.g., laterally outside of the isolation regions 214 where the semiconductor substrate 212 is doped with a p-type dopant). The cathode contact 234 is disposed through the first dielectric layer 230 in the sub-pixel region 202 and electrically contacts the cathode region 220. The anode contacts 232 and cathode contact 234 can be formed by any acceptable processes, and may include silicide, barrier and/or adhesion layer(s), and a conductive fill material (e.g., metal). Generally, no metal pattern disposed in the first dielectric layer 230 is disposed in the sub-pixel region 202 except contact(s) and/or lines to electrically connect to the cathode region 220.

Additional dielectric layers (e.g., second dielectric layer 240, third dielectric layer 250, and fourth dielectric layer 260) are sequentially disposed over the first dielectric layer 230. Like the first dielectric layer 230, the additional dielectric layers (e.g., dielectric layers 240, 250, 260) can each include multiple dielectric layers, such as an etch stop layer (e.g., silicon nitride (SiN) or the like) and an inter-metal dielectric (e.g., an oxide or the like) disposed on the etch stop layer. Metal patterns (e.g., metal patterns 242, 252, 262) are disposed in the additional dielectric layers (e.g., dielectric layers 240, 250, 260, respectively) in the metallization region 150, and no metal pattern disposed in any of the additional dielectric layers is disposed in the sub-pixel region 202. Any number of dielectric layers with or without respective layers of metal patterns may be implemented in a photodetector device 100.

An antireflective surface grating 270 of the sub-pixel region 202 is generically shown in the cross-section of FIG. 4. The antireflective surface grating 270 of the sub-pixel region 202 is disposed at the major surface of the semiconductor substrate 212 and/or the sub-pixel photodiode (e.g., the surface of the cathode region 220). The antireflective surface grating 270, as detailed by subsequent examples, includes components or physical features disposed at the major surface of the semiconductor substrate 212 and/or the sub-pixel photodiode, such as isolation regions and/or dummy gate structures.

The photodetector device 100 is configured such that electromagnetic radiation (e.g., light) can pass through the dielectric layers (e.g., dielectric layers 230, 240, 250, 260), can pass through the antireflective surface grating 270, and be incident on the sub-pixel photodiode. The electromagnetic radiation being incident on the sub-pixel photodiode can cause photons absorbed by the sub-pixel photodiode to be converted by the sub-pixel photodiode to electrons and/or holes to generate an electrical current.

Although described as having sub-pixel regions 102-138, in other examples, any permutation of sub-pixels and/or pixel(s) can be implemented. As an example, the photodetector device 100 may have a single pixel where the sub-pixel photodiodes of the sub-pixel regions 102-138 are electrically connected in parallel. Hence, in such an example, the current generated by the sub-pixel photodiodes of the sub-pixel regions 102-138 can be accumulated to be a signal for the single pixel of the photodetector device 100. In such an example, a pixel antireflective surface grating includes sub-pixel antireflective surface gratings (e.g., antireflective surface grating 270) of the sub-pixel regions 102-138.

As another example, the photodetector device 100 may have multiple pixels, where each pixel has multiple sub-pixels. For example, the sub-pixel photodiodes of the sub-pixel regions 102, 104, 112, 114 can be electrically connected in parallel for a first pixel; the sub-pixel photodiodes of the sub-pixel regions 106, 108, 116, 118 can be electrically connected in parallel for a second pixel; the sub-pixel photodiodes of the sub-pixel regions 122, 124, 132, 134 can be electrically connected in parallel for a third pixel; and the sub-pixel photodiodes of the sub-pixel regions 126, 128, 136, 138 can be electrically connected in parallel for a fourth pixel. In such an example, a first pixel antireflective surface grating includes sub-pixel antireflective surface gratings (e.g., antireflective surface grating 270) of the sub-pixel regions 102, 104, 112, 114; a second pixel antireflective surface grating includes sub-pixel antireflective surface gratings (e.g., antireflective surface grating 270) of the sub-pixel regions 106, 108, 116, 118; etc.

As a further example, the photodetector device 100 may have multiple pixels without any pixel having a sub-pixel. For example, instead of being sub-pixels, each of the regions 102-138 can be a pixel (e.g., a respective photodiode of a pixel may not be electrically connected to a photodiode of another pixel). In such an example, each antireflective surface grating (e.g., antireflective surface grating 270) of the regions 102-138 can be a pixel antireflective surface grating. The general structure shown in FIGS. 3 and 4 may apply irrespective of a distinction between pixel and sub-pixel. Aspects described herein can apply to any permutation.

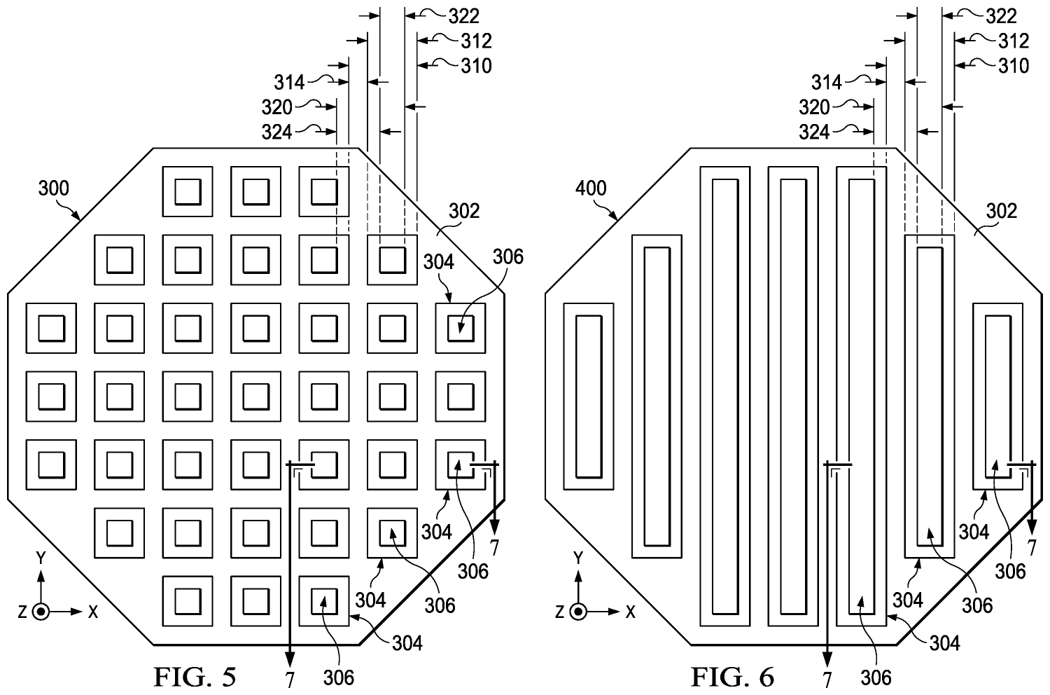

FIGS. 5 through 27 illustrate plan views and cross-sectional views of various sub-pixel antireflective surface gratings consistent with the disclosure. As detailed by these examples, an antireflective surface grating can include or have one or more physical features. An example of a physical feature of an antireflective surface grating is an isolation region. Another example of a physical feature of an antireflective surface grating is or includes a semiconductor surface region of a semiconductor substrate and/or photodiode. Another example of a physical feature of an antireflective surface grating is or includes a dummy gate structure or opening therethrough. An antireflective surface grating can include or have any combination of types of physical features and any configuration of types of physical features. Antireflective surface gratings described below and illustrated in figures include one or more isolation regions 302, one or more semiconductor surface regions 304, one or more dummy gate structures 306, or a combination thereof. For brevity, these components are described generally here.

In various following illustrated examples, such as with reference to FIGS. 5 and 6, an isolation region 302 is disposed at the major surface of the semiconductor substrate 212 and/or the photodiode (e.g., the cathode region 220). The isolation region 302 extends at least from the major surface of the semiconductor substrate 212 and/or the respective photodiode to some depth in the semiconductor substrate 212 and/or the photodiode. The isolation region 302 can be an STI, DTI, LOCOS, or the like. The isolation region 302 includes a dielectric material, such as an oxide, a nitride, the like, or a combination thereof.

In various following illustrated examples, a semiconductor surface region 304 is a portion of the major surface of the semiconductor substrate 212 and/or the photodiode. In some examples, a semiconductor surface region 304 is defined laterally surrounded or encircled by portions of an isolation region 302, and in some examples, an isolation region 302 is defined laterally surrounded or encircled by portions of a semiconductor surface region 304.

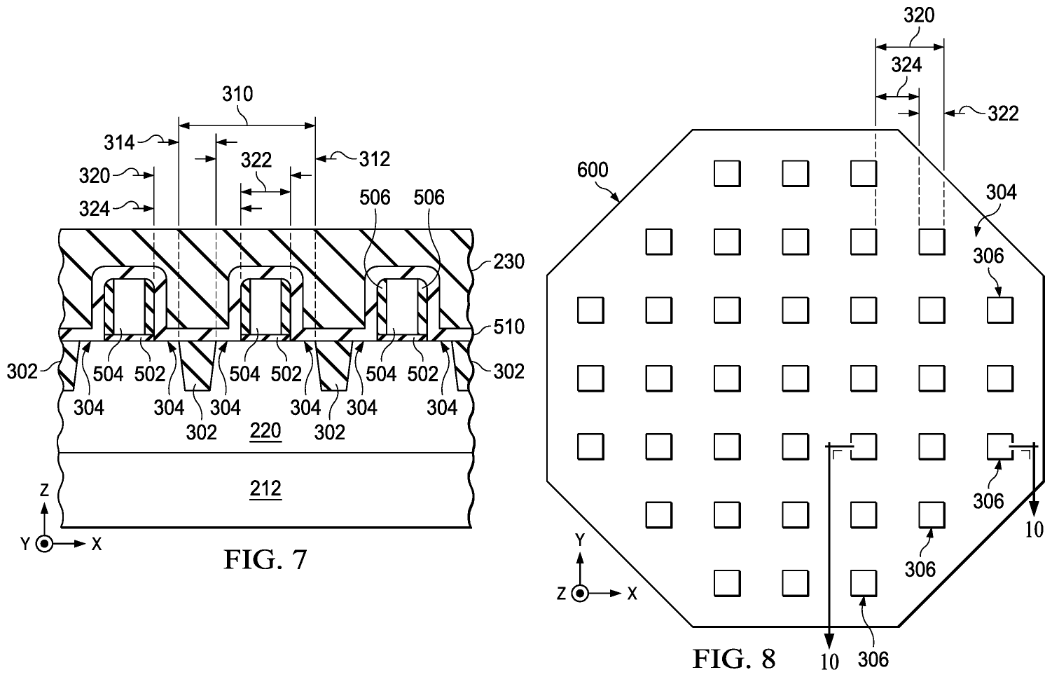

In various following illustrated examples, such as with reference to FIGS. 5 and 6, a dummy gate structure 306 is disposed on or over the major surface of the semiconductor substrate 212 and/or the photodiode and/or on or over an isolation region 302. FIG. 7 shows a cross-section 7 that may further describe the features of FIGS. 5 and 6. The dummy gate structure 306, in some examples, includes a dummy dielectric layer 502 on or over the semiconductor substrate 212 and/or the photodiode and/or on or over an isolation region 302. The dummy gate structure 306 further includes a dummy gate 504 disposed on or over the dummy dielectric layer 502, and includes spacers 506 each disposed on a respective sidewall of the dummy gate 504. In some examples, the dummy dielectric layer 502 is an oxide or any other dielectric layer; the dummy gate 504 is polysilicon, amorphous silicon, or any other appropriate material; and the spacers 506 are silicon nitride (SiN) or any other appropriate material.

Neighboring physical features of a same type aligned along an axis or direction can be described as having a pitch between corresponding lateral boundaries of the respective neighboring physical features. A physical feature can be described as having a dimension between opposing lateral boundaries of the physical feature. Neighboring physical features of a same type aligned along an axis or direction can be described as having a distance between neighboring lateral boundaries of the respective neighboring physical features. Examples of pitches, dimensions, and distances are described below. In the figures described subsequently, the illustrated and described pitches, dimensions, and distances are along a direction parallel to an x-direction. Similar pitches, dimensions, and distances may also be along a direction parallel to a y-direction where appropriate, such as where physical features are described as being arranged in an array.

Generally, as illustrated in various cross-sectional views, a blocking layer 510 may be disposed conformally on an antireflective surface grating. For example, the blocking layer 510 may be disposed conformally on or over the one or more isolation regions 302, the one or more semiconductor surface regions 304, and the one or more dummy gate structures 306, as applicable, of an antireflective surface grating. With respect to the dummy gate structures 306, the blocking layer 510 can be disposed conformally along exterior sidewalls of the spacers 506 and on or over top surfaces of the spacers 506 and dummy gates 504. The blocking layer 510 can be any appropriate dielectric layer, such as silicon nitride (SiN) or the like. The blocking layer 510 can be implemented to block silicidation of semiconductor surface regions 304 during processing of other complementary metal-oxide-semiconductor (CMOS) components on the semiconductor substrate 212, for example.

As shown in FIGS. 5 through 27, respective sub-pixel antireflective surface gratings can be disposed at respective surfaces of sub-pixel photodiodes that are electrically connected together, as described above. The sub-pixel antireflective surface gratings of sub-pixel photodiodes that are electrically connected together can form a pixel antireflective surface grating. In the figures described subsequently, a plan view is illustrated in an x-y plane, and a cross-sectional view is illustrated in an x-z plane.

In some examples, in a pixel, a first sub-pixel antireflective surface grating can be any of the sub-pixel antireflective surface gratings of FIGS. 5 through 27, and a second sub-pixel antireflective surface grating can be a different sub-pixel antireflective surface grating of FIGS. 5 through 27. In some examples, in a pixel, a first sub-pixel antireflective surface grating and a second sub-pixel antireflective surface grating can be generally a same sub-pixel antireflective surface grating of the sub-pixel antireflective surface gratings of FIGS. 5 through 27, except with differing pitches. Hence, differences between the first sub-pixel antireflective surface grating and the second sub-pixel antireflective surface grating can introduce multiple different angles of refraction, according to the grating equation, into the pixel.

Referring to FIGS. 5 and 6, plan views of sub-pixel antireflective surface gratings 300, 400 are illustrated according to some examples. The sub-pixel antireflective surface gratings 300, 400 each have a cross-section 7 that is illustrated in FIG. 7.

Each sub-pixel antireflective surface grating 300, 400 includes an isolation region 302, semiconductor surface regions 304, and dummy gate structures 306. The isolation region 302 laterally defines, at least in part, the semiconductor surface regions 304. A respective dummy gate structure 306 is disposed on or over and laterally within (e.g., in x and y-directions) each semiconductor surface region 304.

In the sub-pixel antireflective surface grating 300 of FIG. 5, the semiconductor surface regions 304 (and hence, also the dummy gate structures 306) are arranged in a periodic array in the plan view. Each semiconductor surface region 304 is illustrated as a square, although other rectangles (e.g., elongated) or other shapes may be implemented. A number of discrete semiconductor surface regions 304 are disposed aligned along a direction parallel to the x-direction in each “row,” and a number of discrete semiconductor surface regions 304 are disposed aligned along a direction parallel to the y-direction in each “column.” In the sub-pixel antireflective surface grating 400 of FIG. 6, the semiconductor surface regions 304 are elongated strips longitudinally extending along a direction parallel to the y-direction. Each discrete semiconductor surface region 304 extends substantially across the sub-pixel region longitudinally in parallel with other semiconductor surface regions 304.

FIGS. 5, 6, and 7 show pitches, dimensions, and distances. FIGS. 5, 6, and 7 show a semiconductor pitch 310 between neighboring semiconductor surface regions 304, a semiconductor dimension 312 of a semiconductor surface region 304, a distance/dimension 314, a gate pitch 320 between neighboring dummy gate structures 306, a gate dimension 322 of a dummy gate structure 306, and a gate distance 324 between neighboring dummy gate structures 306. The distance/dimension 314 is a distance between neighboring semiconductor surface regions 304 and/or a dimension of the isolation region 302 between neighboring semiconductor surface regions 304. In FIGS. 5 and 6, the semiconductor pitch 310 repeats for each neighboring pair of semiconductor surface regions 304 aligned along a direction parallel to the x-direction, and the gate pitch 320 repeats for each neighboring pair of dummy gate structures 306 aligned along a direction parallel to the x-direction. Likewise, in FIG. 5, a semiconductor pitch repeats for each neighboring pair of semiconductor surface regions 304 aligned along a direction parallel to the y-direction, and a gate pitch repeats for each neighboring pair of dummy gate structures 306 aligned along a direction parallel to the y-direction.

It is noted that the semiconductor pitch 310 and the gate pitch 320 are considered a same pitch. The semiconductor pitch 310 and the gate pitch 320 both have the same physical features (e.g., one portion of the isolation region 302, one (cumulatively) semiconductor surface region 304, and one dummy gate structure 306) at the same intervals. The gate pitch 320 may be considered to have a phase offset relative to the semiconductor pitch 310.

In FIGS. 5 and 6, the sub-pixel antireflective surface grating 300, 400 has a single pitch periodicity along directions parallel to the x-direction. A length of the semiconductor pitch 310 (or the gate pitch 320) is equal to a period of the periodicity along the directions parallel to the x-direction. Similarly, in FIG. 5, the sub-pixel antireflective surface grating 300 has a single pitch periodicity along directions parallel to the y-direction. A length of a semiconductor pitch (or a gate pitch) is equal to a period of the periodicity along the directions parallel to the y-direction. In FIG. 6, the sub-pixel antireflective surface grating 400 has no periodicity along directions parallel to the y-direction. No period repeats within the sub-pixel antireflective surface grating 400 along directions parallel to the y-direction.

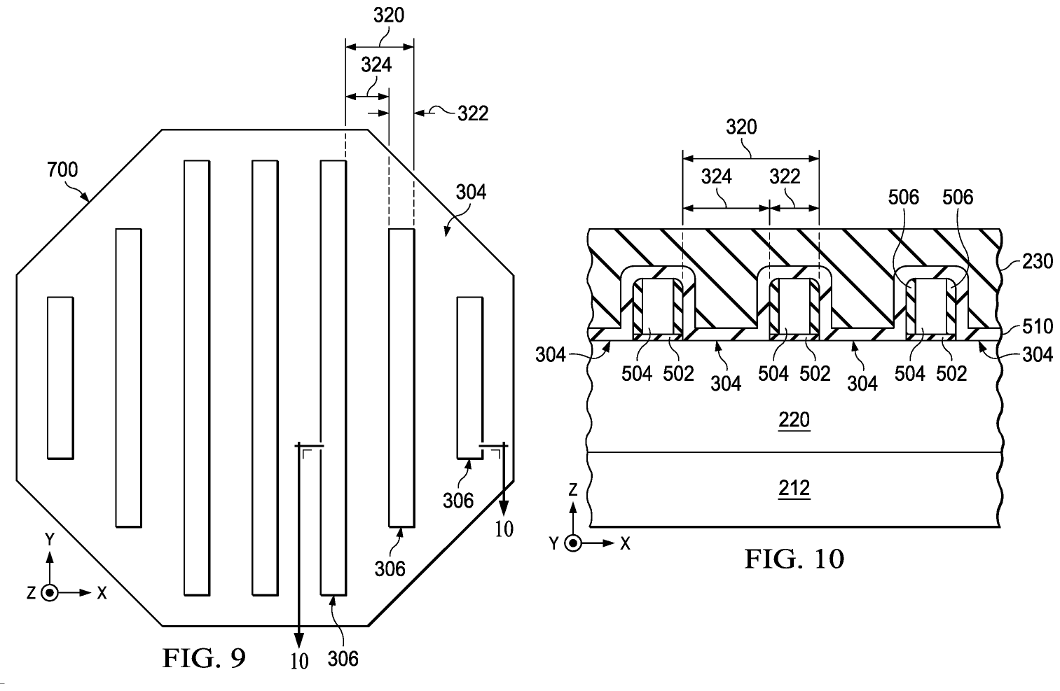

FIGS. 8 and 9 illustrate plan views of sub-pixel antireflective surface gratings 600, 700 according to some examples. The sub-pixel antireflective surface gratings 600, 700 each have a cross-section 10 that is illustrated in FIG. 10. The sub-pixel antireflective surface gratings 600, 700 are like the sub-pixel antireflective surface gratings 300, 400 of FIGS. 5 and 6, respectively, except without the isolation region 302. The absence of the isolation region 302 results in one semiconductor surface region 304 throughout the sub-pixel antireflective surface grating 600, 700. Hence, corresponding pitches, dimensions, and distances of semiconductor surface regions 304 and a dimension of the isolation region 302 are not present in FIGS. 8, 9, and 10. Like FIGS. 5 and 6, the sub-pixel antireflective surface grating 600, 700 of FIGS. 8 and 9, respectively, has a single pitch periodicity along directions parallel to the x-direction. Like FIG. 5, the sub-pixel antireflective surface grating 600 of FIG. 8 has a single pitch periodicity along directions parallel to the y-direction, and like FIG. 6, the sub-pixel antireflective surface grating 700 of FIG. 9 has no periodicity along directions parallel to the y-direction. Further description of FIGS. 8, 9, and 10 is omitted for brevity.

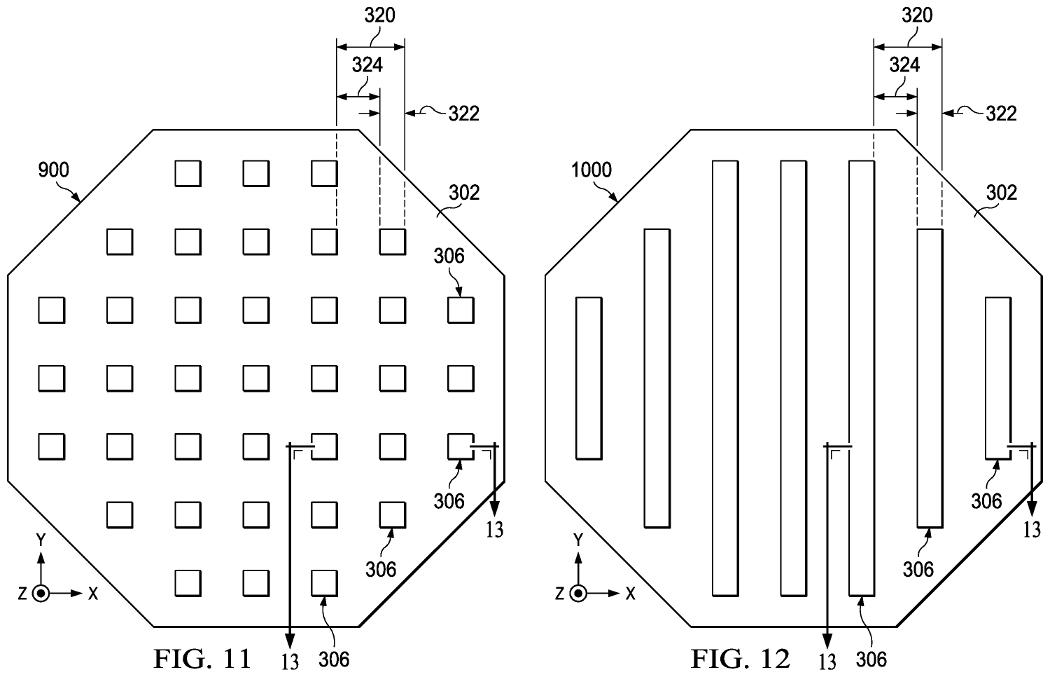

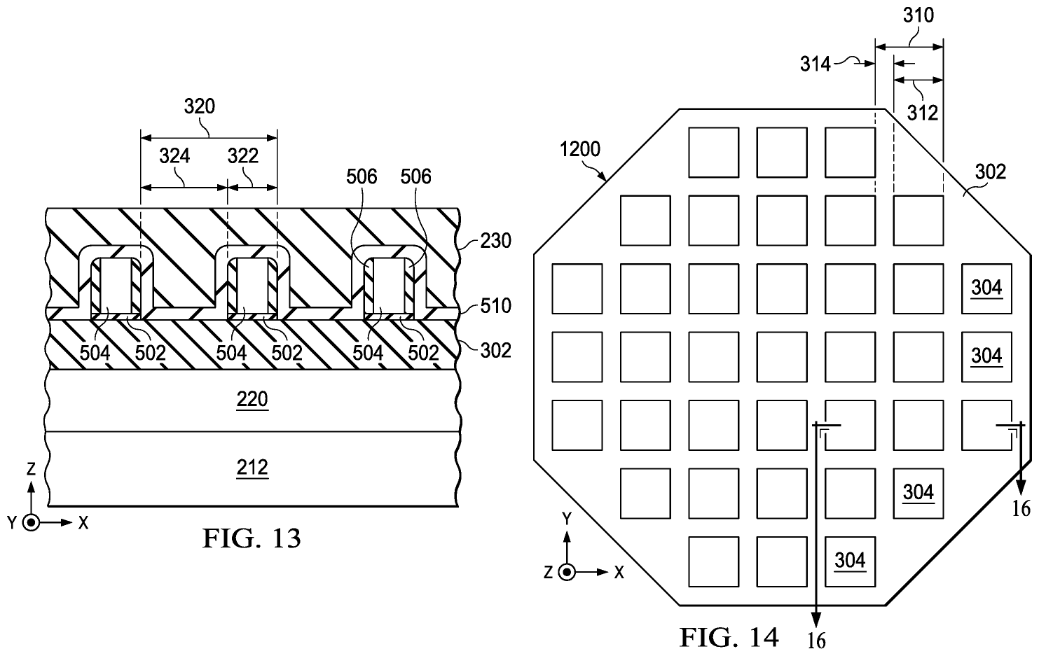

FIGS. 11 and 12 illustrate plan views of sub-pixel antireflective surface gratings 900, 1000 according to some examples. The sub-pixel antireflective surface gratings 900, 1000 each have a cross-section 13 that is illustrated in FIG. 13. The sub-pixel antireflective surface gratings 900, 1000 are like the sub-pixel antireflective surface gratings 300, 400 of FIGS. 5 and 6, respectively, except without the semiconductor surface regions 304. The absence of the semiconductor surface regions 304 results in one isolation region 302 throughout the sub-pixel antireflective surface grating 900, 1000. Hence, corresponding pitches, dimensions, and distances of semiconductor surface regions 304 and a dimension of the isolation region 302 are not present in FIGS. 11, 12, and 13. Like FIGS. 5 and 6, the sub-pixel antireflective surface grating 900, 1000 of FIGS. 11 and 12, respectively, has a single pitch periodicity along directions parallel to the x-direction. Like FIG. 5, the sub-pixel antireflective surface grating 900 of FIG. 11 has a single pitch periodicity along directions parallel to the y-direction, and like FIG. 6, the sub-pixel antireflective surface grating 1000 of FIG. 12 has no periodicity along directions parallel to the y-direction. Further description of FIGS. 11, 12, and 13 is omitted for brevity.

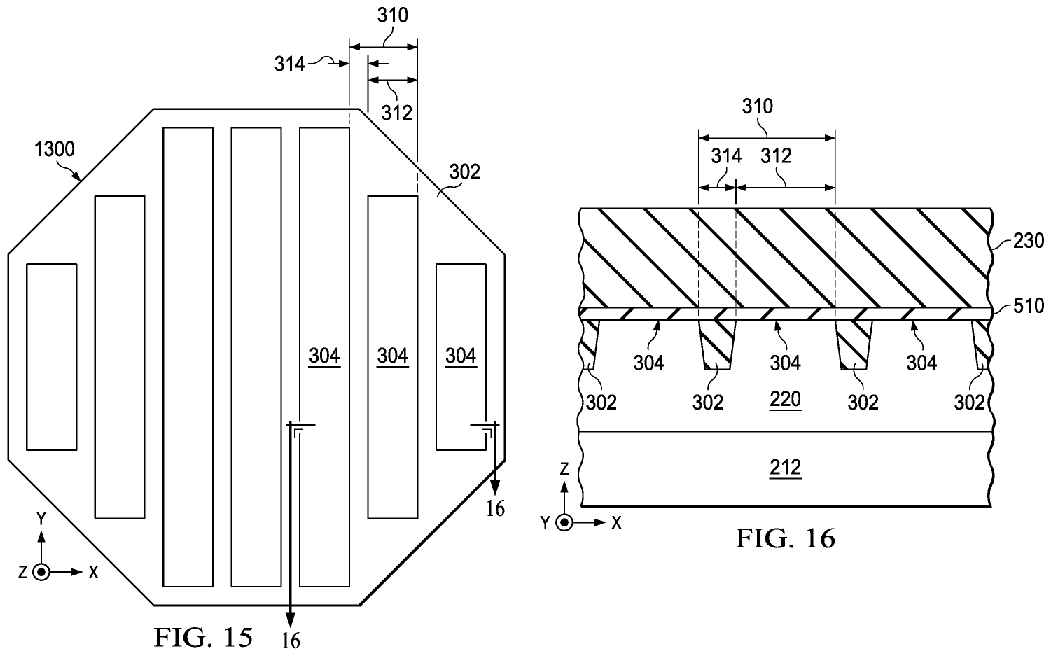

FIGS. 14 and 15 illustrate plan views of sub-pixel antireflective surface gratings 1200, 1300 according to some examples. The sub-pixel antireflective surface gratings 1200, 1300 each have a cross-section 16 that is illustrated in FIG. 16. The sub-pixel antireflective surface gratings 1200, 1300 are like the sub-pixel antireflective surface gratings 300, 400 of FIGS. 5 and 6, respectively, except without dummy gate structures 306 and corresponding gate pitches, dimensions, and distances. The sub-pixel antireflective surface grating 1200, 1300 of FIGS. 14 and 15, respectively, has a single pitch periodicity along directions parallel to the x-direction. The sub-pixel antireflective surface grating 1200 of FIG. 14 has a single pitch periodicity along directions parallel to the y-direction, and the sub-pixel antireflective surface grating 1300 of FIG. 15 has no periodicity along directions parallel to the y-direction. Further description of FIGS. 14, 15, and 16 is omitted for brevity.

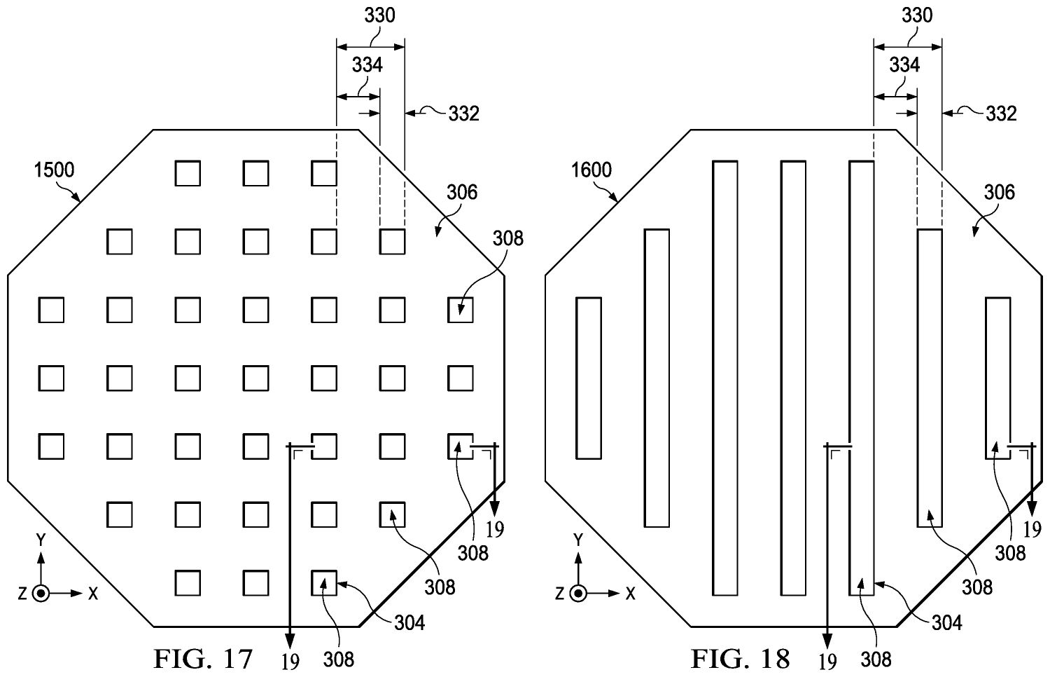

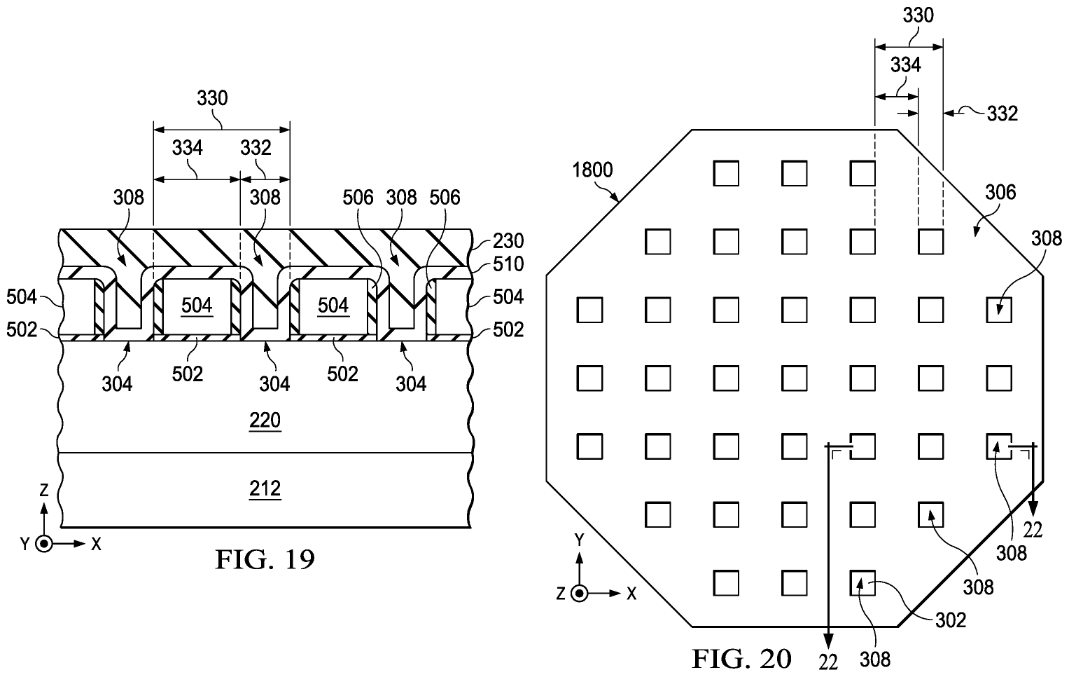

FIGS. 17 and 18 illustrate plan views of sub-pixel antireflective surface gratings 1500, 1600 according to some examples. The sub-pixel antireflective surface gratings 1500, 1600 each have a cross-section 19 that is illustrated in FIG. 19. The sub-pixel antireflective surface gratings 1500, 1600 are like the sub-pixel antireflective surface gratings 600, 700 of FIGS. 8 and 9, respectively, except the dummy gate structure is inverted. Locations where a respective dummy gate structure 306 is disposed in the sub-pixel antireflective surface gratings 600, 700 of FIGS. 8 and 9, respectively, is where an opening through the dummy gate structure 306 is disposed in the sub-pixel antireflective surface gratings 1500, 1600. Similarly, locations where a dummy gate structure 306 is not disposed in the sub-pixel antireflective surface gratings 600, 700 of FIGS. 8 and 9, respectively, is where the dummy gate structure 306 is disposed in the sub-pixel antireflective surface gratings 1500, 1600. The dummy gate structure 306 extends throughout the sub-pixel region and has openings 308 through the dummy gate structure 306.

In the sub-pixel antireflective surface grating 1500 of FIG. 17, the openings 308 are arranged in a periodic array in the plan view. Each opening 308 is illustrated as a square, although other rectangles (e.g., elongated) or other shapes may be implemented. A number of discrete openings 308 are disposed aligned along a direction parallel to the x-direction in each “row,” and a number of discrete openings 308 are disposed aligned along a direction parallel to the y-direction in each “column.” In the sub-pixel antireflective surface grating 1600 of FIG. 18, the openings 308 are elongated openings longitudinally extending along a direction parallel to the y-direction. Each discrete opening 308 extends substantially across the sub-pixel region longitudinally in parallel with other openings 308.

FIGS. 17, 18, and 19 show pitches, dimensions, and distances for the openings 308. FIGS. 17, 18, and 19 show an opening pitch 330 between neighboring openings 308, an opening dimension 332 of an opening 308, and a distance/dimension 334. The distance/dimension 334 is a distance between neighboring openings 308 and/or a dimension of the dummy gate structure 306 between neighboring openings 308.

In FIGS. 17 and 18, the opening pitch 330 repeats for each neighboring pair of openings 308 aligned along a direction parallel to the x-direction. Likewise, in FIG. 17, an opening pitch repeats for each neighboring pair of openings 308 aligned along a direction parallel to the y-direction.

In FIGS. 17 and 18, the sub-pixel antireflective surface grating 1500, 1600 has a single pitch periodicity along directions parallel to the x-direction. A length of the opening pitch 330 is equal to a period of the periodicity along the directions parallel to the x-direction. Similarly, in FIG. 17, the sub-pixel antireflective surface grating 1500 has a single pitch periodicity along directions parallel to the y-direction. A length of an opening pitch is equal to a period of the periodicity along the directions parallel to the y-direction. In FIG. 18, the sub-pixel antireflective surface grating 1600 has no periodicity along directions parallel to the y-direction. No period repeats within the sub-pixel antireflective surface grating 1600 along directions parallel to the y-direction.

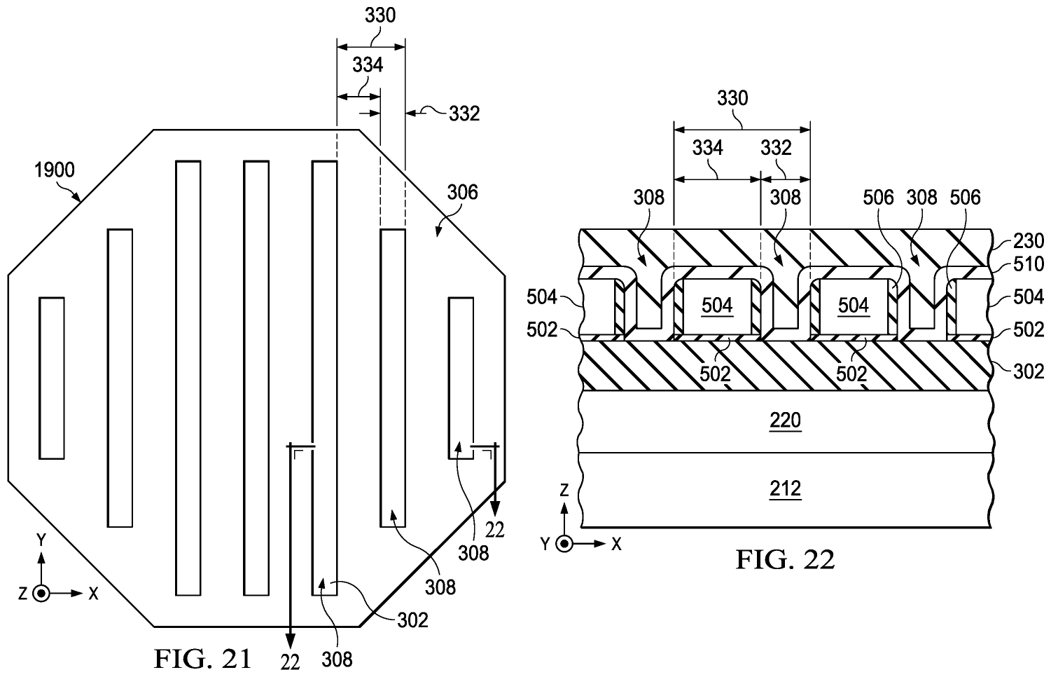

FIGS. 20 and 21 illustrate plan views of sub-pixel antireflective surface gratings 1800, 1900 according to some examples. The sub-pixel antireflective surface gratings 1800, 1900 each have a cross-section 22 that is illustrated in FIG. 22. The sub-pixel antireflective surface gratings 1800, 1900 are like the sub-pixel antireflective surface gratings 900, 1000 of FIGS. 11 and 12, respectively, except the dummy gate structure is inverted like in FIGS. 17 and 18. The sub-pixel antireflective surface grating 1800, 1900 of FIGS. 20 and 21, respectively, has a single pitch periodicity along directions parallel to the x-direction. The sub-pixel antireflective surface grating 1800 of FIG. 20 has a single pitch periodicity along directions parallel to the y-direction, and the sub-pixel antireflective surface grating 1900 of FIG. 21 has no periodicity along directions parallel to the y-direction. Further description of FIGS. 20, 21, and 22 is omitted for brevity.

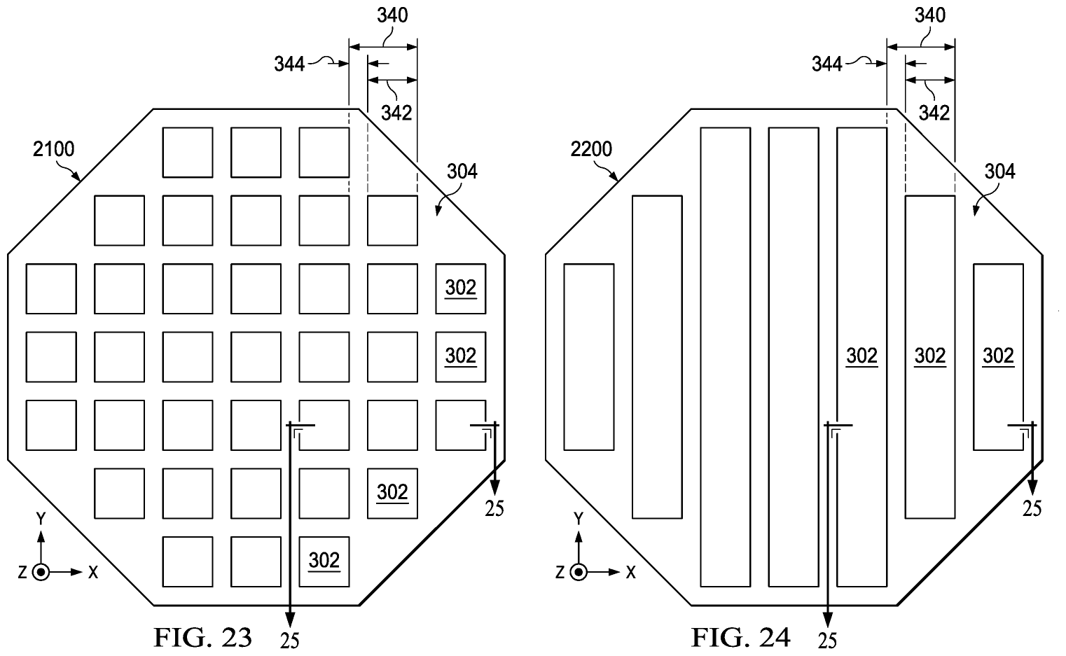

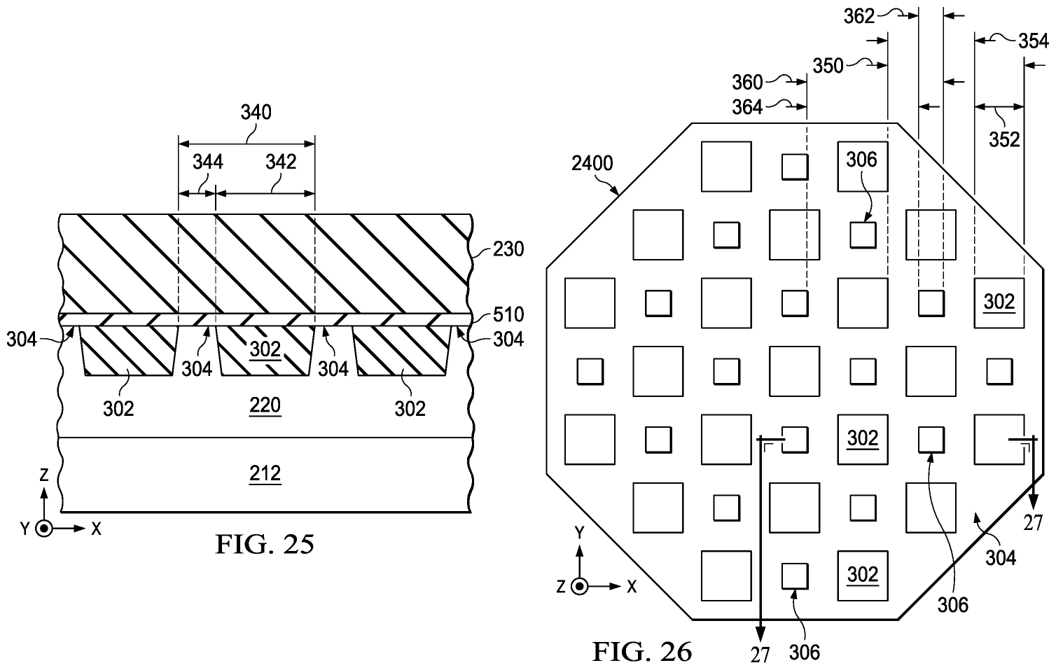

FIGS. 23 and 24 illustrate plan views of sub-pixel antireflective surface gratings 2100, 2200 according to some examples. The sub-pixel antireflective surface gratings 2100, 2200 each have a cross-section 25 that is illustrated in FIG. 25. The sub-pixel antireflective surface gratings 2100, 2200 are like the sub-pixel antireflective surface gratings 1200, 1300 of FIGS. 14 and 15, respectively, except the isolation region 302 and the semiconductor surface regions 304 are inverted. Locations where a respective semiconductor surface region 304 is disposed in the sub-pixel antireflective surface gratings 1200, 1300 of FIGS. 14 and 15, respectively, are where isolation regions 302 are disposed in the sub-pixel antireflective surface gratings 2100, 2200. Similarly, locations where the isolation region 302 is disposed in the sub-pixel antireflective surface gratings 1200, 1300 of FIGS. 14 and 15, respectively, are where the semiconductor surface region 304 is disposed in the sub-pixel antireflective surface gratings 2100, 2200.

FIGS. 23, 24, and 25 show pitches, dimensions, and distances for the isolation regions 302. FIGS. 23, 24, and 25 show an isolation pitch 340 between neighboring isolation regions 302, an isolation dimension 342 of an isolation region 302, and a distance/dimension 344. The distance/dimension 344 is a distance between neighboring isolation regions 302 and/or a dimension of the semiconductor surface region 304 between neighboring isolation regions 302.

In FIGS. 23 and 24, the isolation pitch 340 repeats for each neighboring pair of isolation regions 302 aligned along a direction parallel to the x-direction. Likewise, in FIG. 23, an isolation pitch repeats for each neighboring pair of isolation regions 302 aligned along a direction parallel to the y-direction.

In FIGS. 23 and 24, the sub-pixel antireflective surface grating 2100, 2200 has a single pitch periodicity along directions parallel to the x-direction. A length of the isolation pitch 340 is equal to a period of the periodicity along the directions parallel to the x-direction. Similarly, in FIG. 23, the sub-pixel antireflective surface grating 2100 has a single pitch periodicity along directions parallel to the y-direction. A length of an opening pitch is equal to a period of the periodicity along the directions parallel to the y-direction. In FIG. 24, the sub-pixel antireflective surface grating 2200 has no periodicity along directions parallel to the y-direction. No period repeats within the sub-pixel antireflective surface grating 2200 along directions parallel to the y-direction.

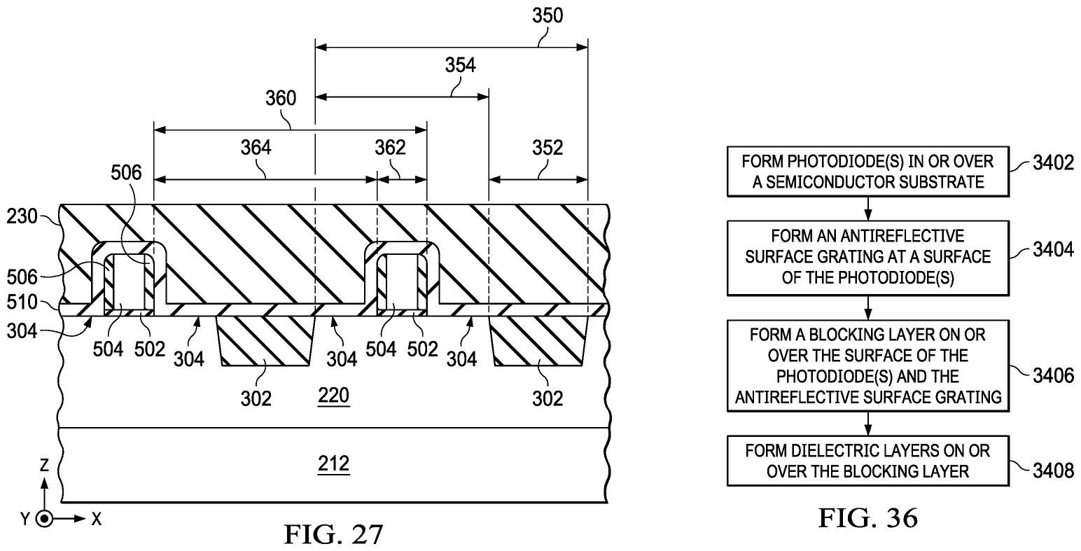

FIG. 26 illustrates a plan view of a sub-pixel antireflective surface grating 2400 according to some examples. The sub-pixel antireflective surface grating 2400 has a cross-section 27 that is illustrated in FIG. 27. The sub-pixel antireflective surface grating 2400 includes isolation regions 302, a semiconductor surface region 304, and dummy gate structures 306. The semiconductor surface region 304 laterally defines, at least in part, the isolation regions 302. Isolation regions 302 and dummy gate structures 306 are disposed alternating along directions parallel to the x-direction and along directions parallel to the y-direction. The isolation regions 302 and the dummy gate structures 306 are together arranged in a periodic array in the plan view. Each isolation region 302 and dummy gate structure 306 is illustrated as a square, although other rectangles (e.g., elongated) or other shapes may be implemented. A number of discrete isolation regions 302 and dummy gate structures 306 are alternatingly disposed aligned along a direction parallel to the x-direction in each “row,” and a number of discrete isolation regions 302 and dummy gate structures 306 are disposed alternatingly aligned along a direction parallel to the y-direction in each “column.”

FIGS. 26 and 27 show pitches, dimensions, and distances. FIGS. 26 and 27 show an isolation pitch 350 between neighboring isolation regions 302, an isolation dimension 352 of an isolation region 302, a distance/dimension 354, a gate pitch 360 between neighboring dummy gate structures 306, a gate dimension 362 of a dummy gate structure 306, and a gate distance 364 between neighboring dummy gate structures 306. The distance/dimension 354 is a distance between neighboring isolation regions 302 and/or a dimension of the semiconductor surface region 304 between neighboring isolation regions 302. In FIG. 26, the isolation pitch 350 repeats for each neighboring pair of isolation regions 302 aligned along a direction parallel to the x-direction, and the gate pitch 360 repeats for each neighboring pair of dummy gate structures 306 aligned along a direction parallel to the x-direction. Likewise, in FIG. 26, an isolation pitch repeats for each neighboring pair of isolation regions 302 aligned along a direction parallel to the y-direction, and a gate pitch repeats for each neighboring pair of dummy gate structures 306 aligned along a direction parallel to the y-direction.

It is noted that the isolation pitch 350 and the gate pitch 360 are considered a same pitch. The isolation pitch 350 and the gate pitch 360 both have the same physical features (e.g., one isolation region 302, one (cumulatively) portion of the semiconductor surface region 304, and one dummy gate structure 306) at the same intervals. The gate pitch 360 may be considered to have a phase offset relative to the isolation pitch 350.

In FIG. 26, the sub-pixel antireflective surface grating 2400 has a single pitch periodicity along directions parallel to the x-direction. A length of the isolation pitch 350 (or the gate pitch 360) is equal to a period of the periodicity along the directions parallel to the x-direction. Similarly, the sub-pixel antireflective surface grating 2400 has a single pitch periodicity along directions parallel to the y-direction. A length of an isolation pitch (or a gate pitch) is equal to a period of the periodicity along the directions parallel to the y-direction.

According to some examples, for sub-pixel photodiodes of a given pixel, a pixel antireflective surface grating includes a first sub-pixel antireflective surface grating and a second sub-pixel antireflective surface grating. A configuration of the first sub-pixel antireflective surface grating is different from a configuration of a second sub-pixel antireflective surface grating. For example, the first sub-pixel antireflective surface grating can be any of the sub-pixel antireflective surface gratings illustrated in FIGS. 5 through 27 or described subsequently, and the second sub-pixel antireflective surface grating can be any different one of the sub-pixel antireflective surface gratings illustrated in FIGS. 5 through 27 or described subsequently.

According to some examples, for sub-pixel photodiodes of a given pixel, a pixel antireflective surface grating includes a first sub-pixel antireflective surface grating and a second sub-pixel antireflective surface grating. In some examples, the configurations of the first and second sub-pixel antireflective surface gratings may generally correspond with each other, except with one or more differences between corresponding physical features of the different sub-pixel antireflective surface gratings, such as differences between semiconductor surface regions 304 and isolation regions 306 between FIGS. 5 and 6.

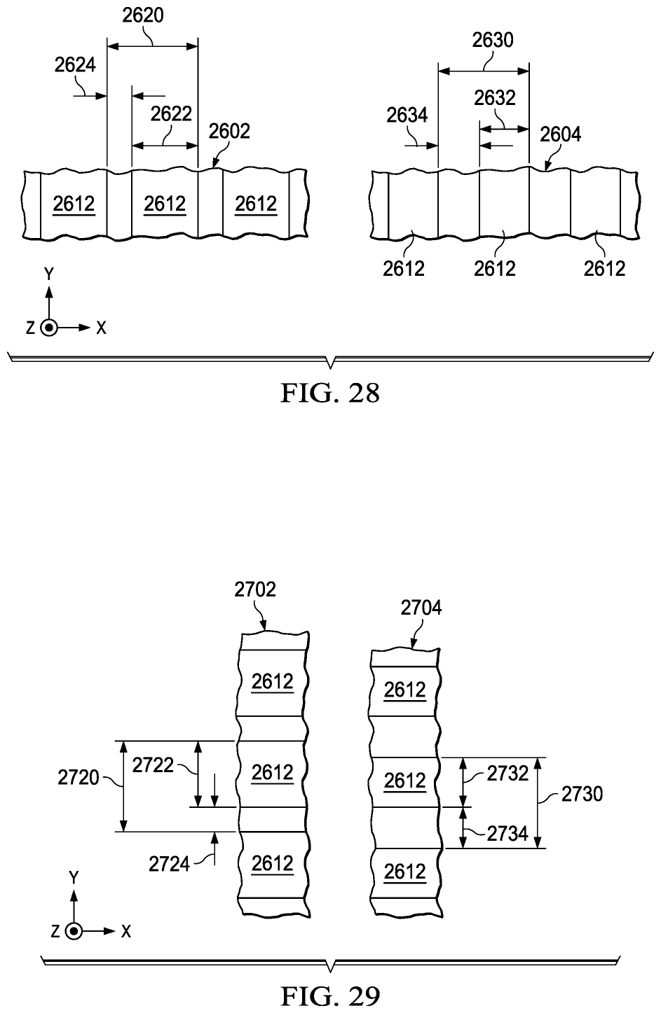

According to some examples, for sub-pixel photodiodes of a given pixel, a pixel antireflective surface grating includes a first sub-pixel antireflective surface grating and a second sub-pixel antireflective surface grating. In some examples, the first and second sub-pixel antireflective surface gratings can generally correspond to each other and each can have a single pitch periodicity along directions parallel to a same lateral direction (e.g., an x-direction and/or y-direction in the illustrations described above). The pitches that result in the single pitch periodicities of the first and second sub-pixel antireflective surface gratings differ. For example, the pitches can differ in lengths of the pitches, dimensions of corresponding physical features in the pitches, distances in the pitches between corresponding neighboring physical features, or a combination thereof. FIGS. 28 through 31 illustrate examples showing how pitches may differ.

FIG. 28 shows a layout of respective portions of generalized sub-pixel antireflective surface gratings 2602, 2604 according to some examples. FIG. 28 illustrates generally different dimensions and distances that may be implemented in the sub-pixel antireflective surface gratings 2602, 2604 to achieve different pitches. Each sub-pixel antireflective surface grating 2602, 2604 includes multiple general physical features 2612 of a same feature type aligned along a direction parallel to the x-direction. The physical features 2612 can be isolation regions 302 in some examples. The physical features 2612 can be semiconductor surface regions 304 in some examples. The physical features 2612 can be dummy gate structures 306 in some examples. The physical features 2612 can be openings 308 through a dummy gate structure 306 in some examples.

In the sub-pixel antireflective surface grating 2602, a pitch 2620 is between neighboring physical features 2612. A dimension 2622 of a physical feature 2612 is shown in the sub-pixel antireflective surface grating 2602. A distance 2624 is between neighboring physical features 2612.

In the sub-pixel antireflective surface grating 2604, a pitch 2630 is between neighboring physical features 2612. A dimension 2632 of a physical feature 2612 is shown in the sub-pixel antireflective surface grating 2602. A distance 2634 is between neighboring physical features 2612.

The pitches 2620, 2630, dimensions 2622, 2632, and distances 2624, 2634 in FIG. 28 are aligned along a same axis. In the illustration, the axis is parallel to an x-direction. The lengths of the pitches 2620, 2630 are equal to each other. The dimensions 2622, 2632 are not equal to each other, and the distances 2624, 2634 are not equal to each other.

FIG. 29 shows a layout of respective portions of generalized sub-pixel antireflective surface gratings 2702, 2704 according to some examples. FIG. 29 illustrates generally different dimensions and distances that may be implemented in the sub-pixel antireflective surface gratings 2702, 2704 to achieve different pitches. Each sub-pixel antireflective surface grating 2702, 2704 includes multiple general physical features 2612 of a same feature type aligned along a direction parallel to the y-direction.

In the sub-pixel antireflective surface grating 2702, a pitch 2720 is between neighboring physical features 2612. A dimension 2722 of a physical feature 2612 is shown in the sub-pixel antireflective surface grating 2702. A distance 2724 is between neighboring physical features 2612.

In the sub-pixel antireflective surface grating 2704, a pitch 2730 is between neighboring physical features 2612. A dimension 2732 of a physical feature 2612 is shown in the sub-pixel antireflective surface grating 2702. A distance 2734 is between neighboring physical features 2612.

The pitches 2720, 2730, dimensions 2722, 2732, and distances 2724, 2734 in FIG. 29 are along different axes. In the illustration, the different axes are parallel to the y-direction. The lengths of the pitches 2720, 2730 are equal to each other. The dimensions 2722, 2732 are not equal to each other, and the distances 2724, 2734 are not equal to each other.

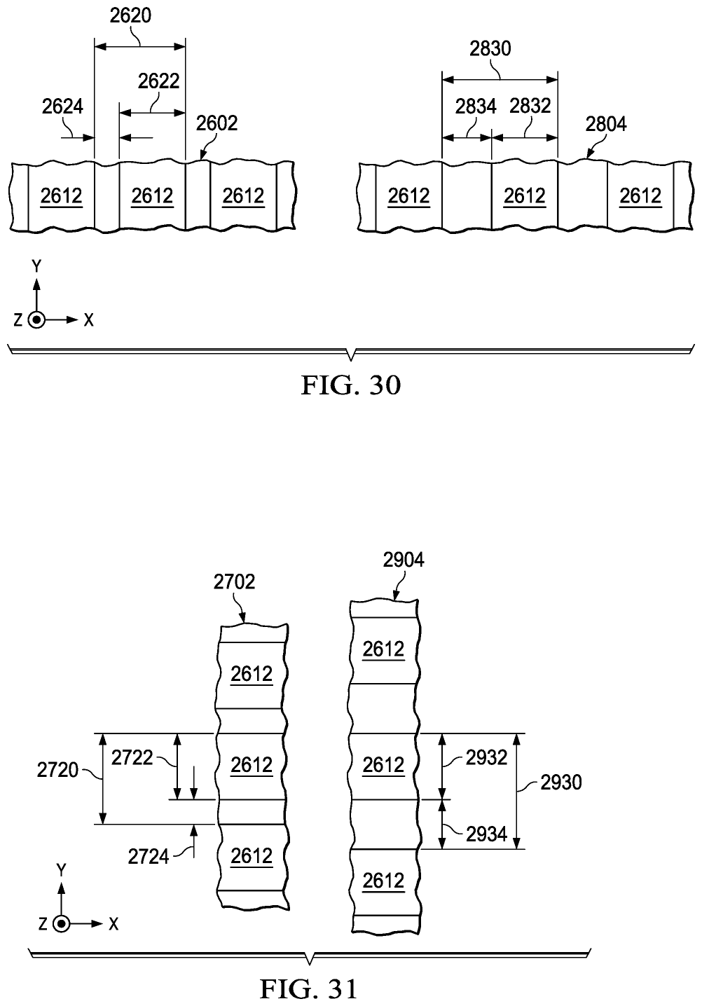

FIG. 30 shows a layout of respective portions of generalized sub-pixel antireflective surface gratings 2602, 2804 according to some examples. FIG. 30 illustrates generally different lengths of pitches and distances (and/or dimensions) that may be implemented in the sub-pixel antireflective surface gratings 2602, 2804 to achieve different pitches. The sub-pixel antireflective surface grating 2602 is as described above with respect to FIG. 28. Similarly, the sub-pixel antireflective surface grating 2804 includes multiple general physical features 2612. In the sub-pixel antireflective surface grating 2804, a pitch 2830 is between neighboring physical features 2612. A dimension 2832 of a physical feature 2612 is shown in the sub-pixel antireflective surface grating 2804. A distance 2834 is between neighboring physical features 2612.

The pitches 2620, 2830, dimensions 2622, 2832, and distances 2624, 2834 in FIG. 30 are aligned along a same axis. In the illustration, the axis is parallel to an x-direction. The lengths of pitches 2620, 2830 are not equal to each other, and the distances 2624, 2834 are not equal to each other. The dimensions 2622, 2832 are equal to each other, and in other examples, may not be equal to each other.

FIG. 31 shows a layout of respective portions of generalized sub-pixel antireflective surface gratings 2702, 2904 according to some examples. FIG. 29 illustrates generally different pitches and distances (or dimensions) that may be implemented in the sub-pixel antireflective surface gratings 2702, 2904 to achieve different pitches. The sub-pixel antireflective surface grating 2702 is as described above with respect to FIG. 29. Similarly, the sub-pixel antireflective surface grating 2904 includes multiple general physical features 2612 of a same feature type aligned along a direction parallel to the y-direction. In the sub-pixel antireflective surface grating 2904, a pitch 2930 is between neighboring physical features 2612. A dimension 2932 of a physical feature 2612 is shown in the sub-pixel antireflective surface grating 2904. A distance 2934 is between neighboring physical features 2612.

The pitches 2720, 2930, dimensions 2722, 2932, and distances 2724, 2934 in FIG. 31 are along different axes. In the illustration, the different axes are parallel to a y-direction. The lengths of the pitches 2720, 2930 are not equal to each other, and the distances 2724, 2934 are not equal to each other. The dimensions 2722, 2932 are equal to each other, and in other examples, may not be equal to each other.

It has been observed that interference oscillation amplitudes can be reduced by implementing examples described above. A test included eleven sample photodetector devices. Each sample included a pixel comprising four sub-pixel regions, where the respective sub-pixel photodiodes of the four sub-pixel regions were electrically connected in parallel. In Sample 0, no antireflective surface grating was implemented. In each of Samples 1 through 4, a pixel antireflective surface grating including sub-pixel antireflective surface gratings was implemented, where each sub-pixel antireflective surface grating included an isolation region without a dummy gate structure (e.g., like in FIG. 14). Each sub-pixel antireflective surface grating of a pixel antireflective surface grating of a given sample implemented the same periodic structure. The periodicity of Samples 1 through 4 differed between the samples. In Sample 5, a pixel antireflective surface grating including sub-pixel antireflective surface gratings was implemented, where each sub-pixel antireflective surface grating included an isolation region without a dummy gate structure (e.g., like in FIG. 14). Each sub-pixel antireflective surface grating of the pixel antireflective surface grating of Sample 5 had a different periodic structure that was a respective (different) one of the Samples 1 through 4. Samples 6 through 10 were the same as Samples 1 through 5, except the antireflective surface gratings of Samples 6 through 10 included dummy gate structures (e.g., like FIG. 5).

It was observed that each of Samples 1 through 10 resulted in a signal that had reduced interference oscillation amplitudes relative to Sample 0 (without an antireflective surface grating). Further, across multiple tests, it was observed that overall average interference oscillation amplitudes of signals obtained from Sample 5 (having multiple periodicities) was reduced relative to each of Samples 1 through 4. Similarly, across multiple tests, it was observed that overall average interference oscillation amplitudes of signals obtained from Sample 10 (having multiple periodicities) was reduced relative to each of Samples 6 through 9. Also, it was observed that overall average interference oscillation amplitudes of signals obtained from Sample 10 (with dummy gate structures and multiple periodicities) was reduced relative to Sample 5 (without dummy gate structures and with multiple periodicities).

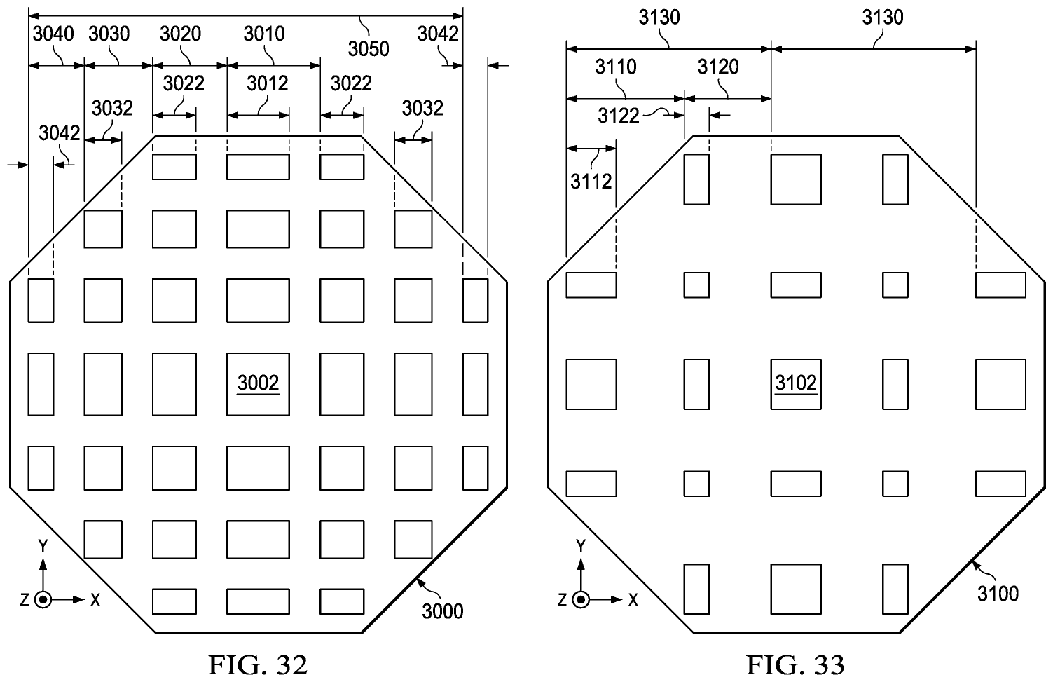

FIG. 32 illustrates a plan view of an antireflective surface grating 3000 according to some examples. The antireflective surface grating 3000 can be for a sub-pixel photodiode or a single pixel photodiode. The antireflective surface grating 3000 includes general physical features 3002 of a same feature type, which may be an isolation region, semiconductor surface region dummy gate structure, or any combination thereof. Although specific aspects are illustrated and described with respect to directions parallel to the x-direction, such aspects are likewise applicable to directions parallel to the y-direction in the illustrated example. In other examples, the aspects may not be applicable, such as when the physical features are elongated extending across the photodiode.

Multiple pitches between neighboring physical features 3002 aligned along directions parallel to the x-direction are shown. For example, FIG. 32 illustrates a largest-length pitch 3010 and a smallest-length pitch 3040, with successively smaller-length pitches 3020, 3030 therebetween. Dimensions of the physical features 3002 vary from physical feature 3002 to physical feature 3002 along directions parallel to the x-direction. For example, FIG. 32 illustrates a largest dimension 3012 and a smallest dimension 3042, with successively smaller dimensions 3022, 3032 therebetween. The distances between neighboring physical features 3002 in directions parallel to the x-direction are equal in the illustrated example. In other examples, these distances can also vary.

FIG. 32 shows a period 3050. While the antireflective surface grating 3000 of FIG. 32 does not expressly illustrate periodicity because the period 3050 is not repeated, the pattern illustrated in FIG. 32 can be repeated along directions parallel to the x-direction and directions parallel to the y-direction such that periodicity can be achieved in an antireflective surface grating. The period 3050 includes multiple different pitches (e.g., pitch 3010, two pitches 3020, two pitches 3030, and pitch 3040). If the pattern of FIG. 32 is repeated to achieve periodicity, such antireflective surface grating would have a periodicity having a period 3050 that includes multiple pitches.

FIG. 33 illustrates a plan view of an antireflective surface grating 3100 according to some examples. The antireflective surface grating 3100 can be for a sub-pixel photodiode or a single pixel photodiode. The antireflective surface grating 3100 includes general physical features 3102 of a same feature type, which may be an isolation region, semiconductor surface region dummy gate structure, or any combination thereof. Although specific aspects are illustrated and described with respect to directions parallel to the x-direction, such aspects are likewise applicable to directions parallel to the y-direction in the illustrated example. In other examples, the aspects may not be applicable, such as when the physical features are elongated extending across the photodiode.

Multiple pitches between neighboring physical features 3102 aligned along directions parallel to the x-direction are shown. For example, FIG. 33 illustrates a first pitch 3110 and a second pitch 3120. Unequal dimensions of the physical features 3102 alternate from physical feature 3102 to physical feature 3102 along directions parallel to the x-direction. For example, FIG. 33 illustrates a first dimension 3112 and a second dimension 3122. The distances between neighboring physical features 3102 in directions parallel to the x-direction are equal in the illustrated example. In other examples, these distances can also vary.

FIG. 33 shows a period 3130. The period 3130 is repeated along directions parallel to the x-direction. The period 3130 includes multiple different pitches (e.g., first pitch 3110 and second pitch 3120). Hence, the antireflective surface grating 3100 has a periodicity having a period that includes multiple pitches.

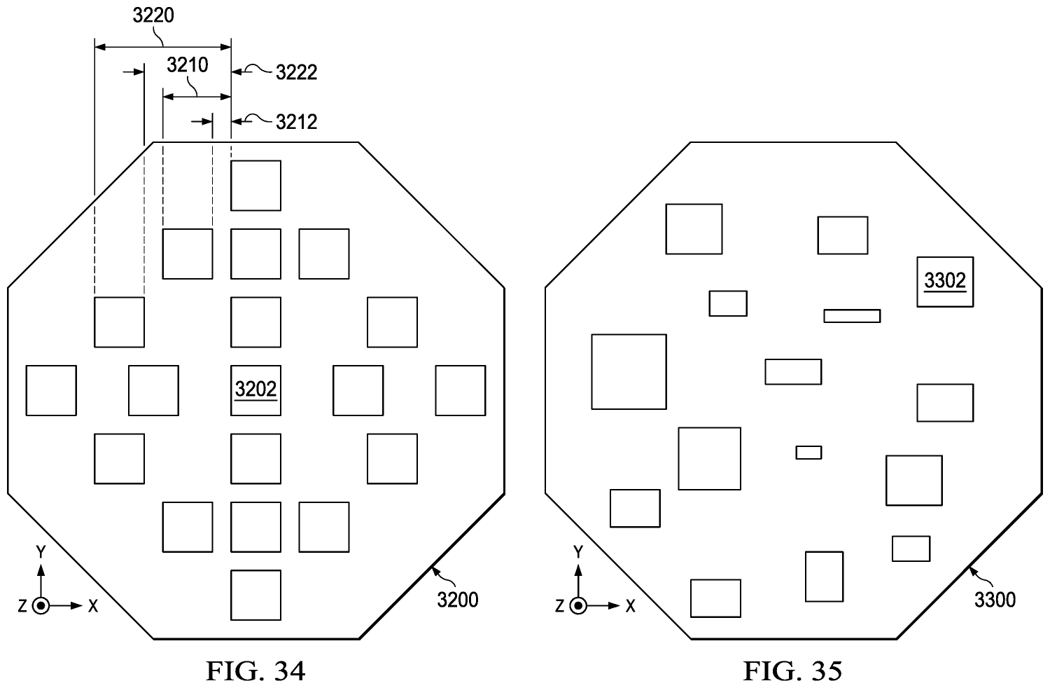

FIG. 34 illustrates a plan view of an antireflective surface grating 3200 according to some examples. The antireflective surface grating 3200 can be for a sub-pixel photodiode or a single pixel photodiode. The antireflective surface grating 3200 includes general physical features 3202 of a same feature type, which may be an isolation region, semiconductor surface region dummy gate structure, or any combination thereof. Although specific aspects are illustrated and described with respect to directions parallel to the x-direction, such aspects are likewise applicable to directions parallel to the y-direction in the illustrated example.

Multiple pitches between neighboring physical features 3202 aligned along directions parallel to the x-direction are shown. For example, FIG. 34 illustrates a first pitch 3210 and a second pitch 3220 as examples. The length of the first pitch 3210 is not equal to the length of the second pitch 3220. Dimensions of the physical features 3202 are equal along directions parallel to the x-direction. Multiple distances between neighboring physical features 3202 in directions parallel to the x-direction are shown. For example, FIG. 34 illustrates a first distance 3212 (in the first pitch 3210) and a second distance 3222 (in the second pitch 3220). The first distance 3212 is not equal to the second distance 3222. The second pitch 3220 and the second distance 3222 are larger than the first pitch 3210 and the first distance 3212, respectively.

The antireflective surface grating 3200 of FIG. 34 has multiple periodicities aligned along directions parallel to the x-direction. A period of a first periodicity, for example, is equal to the length of the first pitch 3210, and hence, the first periodicity may be a single pitch periodicity. A period of a second periodicity, for example, is equal to the length of the second pitch 3220, and hence, the second periodicity may be a single pitch periodicity. Accordingly, the antireflective surface grating 3200 has periodicities having respective periods that collectively include multiple pitches.

FIG. 35 illustrates a plan view of an antireflective surface grating 3300 according to some examples. The antireflective surface grating 3300 can be for a sub-pixel photodiode or a single pixel photodiode. The antireflective surface grating 3300 includes general physical features 3302 of a same feature type, which may be an isolation region, semiconductor surface region dummy gate structure, or any combination thereof. The physical features 3302 are located at random locations in the antireflective surface grating 3300. The antireflective surface grating 3300 has no periodicity in directions parallel to the x-direction and to the y-direction. In some examples, an antireflective surface grating can have random locations of physical features in directions parallel to a lateral direction and can have periodicity of those physical features in a direction parallel to another lateral direction.

According to some examples, for sub-pixel photodiodes of a given pixel, a pixel antireflective surface grating includes a first sub-pixel antireflective surface grating and a second sub-pixel antireflective surface grating. In some examples, the first and second sub-pixel antireflective surface gratings can each have a multiple pitch periodicity along directions parallel to a same lateral direction, like illustrated in FIG. 33 and explained in the context of FIG. 32. At least one pitch of the first sub-pixel antireflective surface grating differs from at least one pitch of the second sub-pixel antireflective surface grating. For example, where the antireflective surface grating 3100 of FIG. 33 is implemented for each of the first and second sub-pixel antireflective surface gratings (e.g., the same configuration is implemented for the first and second sub-pixel antireflective surface gratings), the first pitch 3110 of the first sub-pixel antireflective surface gratings differs from the second pitch 3120 of the second sub-pixel antireflective surface grating. The first and second sub-pixel antireflective surface gratings can each have a same multiple pitch periodicity along directions parallel to a same lateral direction.

According to some examples, for sub-pixel photodiodes of a given pixel, a pixel antireflective surface grating includes a first sub-pixel antireflective surface grating and a second sub-pixel antireflective surface grating. In some examples, the first and second sub-pixel antireflective surface gratings can each have multiple single pitch periodicities along directions parallel to a same lateral direction, like illustrated in FIG. 34. At least one pitch of the first sub-pixel antireflective surface grating differs from at least one pitch of the second sub-pixel antireflective surface grating. For example, where the antireflective surface grating 3200 of FIG. 34 is implemented for each of the first and second sub-pixel antireflective surface gratings (e.g., the same configuration is implemented for the first and second sub-pixel antireflective surface gratings), the first pitch 3210 of the first sub-pixel antireflective surface gratings differs from the second pitch 3220 of the second sub-pixel antireflective surface grating. The first and second sub-pixel antireflective surface gratings can each have same multiple single pitch periodicities along directions parallel to the same lateral direction.

According to some examples, for sub-pixel photodiodes of a given pixel, a pixel antireflective surface grating includes a first sub-pixel antireflective surface grating and a second sub-pixel antireflective surface grating. In some examples, the configurations of first and second sub-pixel antireflective surface gratings are the same, and physical features of the first and second sub-pixel antireflective surface gratings can be randomly located within the respective antireflective surface grating such that no periodicity occurs, like in FIG. 35.

According to some examples, for a single pixel photodiode, the single pixel antireflective surface grating at the surface of that photodiode can have a multiple pitch periodicity along directions parallel to a lateral direction, like in FIG. 34 and explained in the context of FIG. 32. According to some examples, for a single pixel photodiode, the single pixel antireflective surface grating at the surface of that photodiode can have multiple single pitch periodicities along directions parallel to a lateral direction, like in FIG. 33. According to some examples, for a single pixel photodiode, physical features of the antireflective surface grating can be randomly located within the antireflective surface grating such that no periodicity occurs in the antireflective surface grating, like in FIG. 35.

FIG. 36 is a method for semiconductor processing to form a photodetector device according to some examples. At block 3402, one or more photodiodes are formed in or over a semiconductor substrate. For example, each photodiode can include a cathode and an anode having the structure illustrated in and described with respect to FIG. 4. Forming the one or more photodiodes can include implanting dopants and/or epitaxially growing a semiconductor layer that is in-situ doped, for example. In some examples, each photodiode can be for a respective pixel (e.g., without sub-pixels). In some examples, multiple photodiodes (e.g., sub-pixel photodiodes) can be for a given pixel.

At block 3404, an antireflective surface grating is formed at a surface of the one or more photodiodes. The antireflective surface grating can have the structure of any antireflective surface grating as described above. Forming the antireflective surface grating can include any appropriate processing to form an isolation region, such as an STI, DTI, or LOCOS, and can include any appropriate processing to form a gate structure, such as used in CMOS processing.

It is noted that blocks 3402, 3404 are generally described without regard to an order of processing, and the particular processing and order thereof may vary and may depend on a specific implementation. For example, epitaxial growth of a semiconductor layer with in-situ doping for an anode of a photodiode can be performed, followed by forming isolation regions of an antireflective surface grating at a surface of the semiconductor layer. Then, an implant into the semiconductor layer to form a cathode of the photodiode can be performed, followed by forming gate structures of the antireflective surface grating on or over the semiconductor layer. In another example, isolation regions of an antireflective surface grating are formed at a surface of a semiconductor substrate, followed by implants to form an anode and a cathode in the semiconductor substrate. Then, gate structures of the antireflective surface grating are formed on or over the semiconductor substrate. In some examples, forming isolation regions may be omitted when the antireflective surface grating does not include isolation regions. In some examples, forming gate structures may be omitted when the antireflective surface grating does not include isolation regions.

At block 3406, a blocking layer is formed on or over the surface of the one or more photodiodes and the antireflective surface grating. The blocking layer can be deposited by any conformal deposition process, such as chemical vapor deposition (CVD), atomic layer deposition (ALD), or the like. At block 3408, dielectric layers are formed on or over the blocking layer. The dielectric layers can be formed by depositing inter-layer dielectric (ILD) and/or inter-metal dielectric (IMD) layers with or without metal patterns therein as used in CMOS processing.

Although various examples have been described in detail, it should be understood that various changes, substitutions, and alterations can be made therein without departing from the scope defined by the appended claims.

What is claimed is:

1. A semiconductor device structure comprising:
a photodetector device comprising:
one or more photodiodes disposed in or over a semiconductor substrate; and
a surface grating disposed at a respective surface of each photodiode of the one or more photodiodes, the surface grating having one or more periodicities, each periodicity of the one or more periodicities having a period that is along a direction parallel to a first lateral direction across the semiconductor substrate and that is equal to or less than half of a dimension of at least one photodiode of the one or more photodiodes along a direction parallel to the first lateral direction, the one or more periodicities including multiple different pitches.

2. The semiconductor device structure of claim 1, wherein:
the one or more periodicities include a first periodicity and a second periodicity;
the period of the first periodicity includes a first pitch of the multiple different pitches; and
the period of the second periodicity includes a second pitch of the multiple different pitches, the second pitch being different from the first pitch.

3. The semiconductor device structure of claim 1, wherein the period of a periodicity of the one or more periodicities includes the multiple different pitches.

4. The semiconductor device structure of claim 1, wherein:
the one or more photodiodes include:
a first sub-pixel photodiode disposed in or over the semiconductor substrate; and
a second sub-pixel photodiode disposed in or over the semiconductor substrate, the first sub-pixel photodiode and the second sub-pixel photodiode being electrically connected together in parallel in the photodetector device; and
the surface grating includes:
a first sub-pixel surface grating disposed at a surface of the first sub-pixel photodiode, the first sub-pixel surface grating having a first periodicity of the one or more periodicities, the period of the first periodicity being equal to a length of a first pitch of the multiple different pitches; and
a second sub-pixel surface grating disposed at a surface of the second sub-pixel photodiode, the second sub-pixel surface grating having a second periodicity of the one or more periodicities, the period of the second periodicity being equal to a length of a second pitch of the multiple different pitches, the first pitch and the second pitch being different.

5. The semiconductor device structure of claim 1, wherein:
the multiple different pitches includes a first pitch and a second pitch different from the first pitch;
the first pitch is between corresponding lateral boundaries of a first pair of neighboring physical features of a same type aligned along a direction parallel to the first lateral direction, the first pitch includes a first distance between neighboring lateral boundaries of the neighboring physical features of the first pair;
the second pitch is between corresponding lateral boundaries of a second pair of neighboring physical features of the same type aligned along a direction parallel to the first lateral direction, the second pitch includes a second distance between neighboring lateral boundaries of the neighboring physical features of the second pair; and
the first distance is not equal to the second distance.

6. The semiconductor device structure of claim 1, wherein:
the multiple different pitches includes a first pitch and a second pitch different from the first pitch;
the first pitch is between corresponding lateral boundaries of a first pair of neighboring physical features of a same type aligned along a direction parallel to the first lateral direction, the first pitch includes a first lateral dimension of one physical feature of the first pair;
the second pitch is between corresponding lateral boundaries of a second pair of neighboring physical features of the same type aligned along a direction parallel to the first lateral direction, the second pitch includes a second lateral dimension of one physical feature of the second pair; and
the first lateral dimension is not equal to the second lateral dimension.

7. The semiconductor device structure of claim 1, wherein:
the multiple different pitches includes a first pitch and a second pitch different from the first pitch;
the first pitch is between corresponding lateral boundaries of a first pair of neighboring physical features of a same type aligned along a direction parallel to the first lateral direction;
the second pitch is between corresponding lateral boundaries of a second pair of neighboring physical features of the same type aligned along a direction parallel to the first lateral direction; and
a length of the first pitch is not equal to a length of the second pitch.

8. The semiconductor device structure of claim 1, wherein the surface grating includes, at each photodiode of the one or more photodiodes, an isolation region and semiconductor surface regions defined by the isolation region, the isolation region extending from the respective surface of the respective photodiode to a depth in the respective photodiode, the semiconductor surface regions being in the respective surface of the respective photodiode.

9. The semiconductor device structure of claim 1, wherein the surface grating includes, at each photodiode of the one or more photodiodes, a semiconductor surface region and isolation regions defined by the semiconductor surface region, the isolation regions extending from the respective surface of the respective photodiode to a respective depth in the respective photodiode, the semiconductor surface region being in the respective surface of the respective photodiode.

10. The semiconductor device structure of claim 1, wherein the surface grating includes, at each photodiode of the one or more photodiodes, dummy gate structures on or over the respective surface of the respective photodiode.

11. The semiconductor device structure of claim 1, wherein the surface grating includes, at each photodiode of the one or more photodiodes, a dummy gate structure on or over the respective surface of the respective photodiode, openings extending through the dummy gate structure.

12. A semiconductor device structure comprising:
a photodetector device comprising:
a first sub-pixel photodiode disposed in or over a semiconductor substrate; and
a second sub-pixel photodiode disposed in or over the semiconductor substrate, the first sub-pixel photodiode being electrically connected in parallel with the second sub-pixel photodiode; and
a surface grating comprising:
a first sub-pixel surface grating disposed at a surface of the first sub-pixel photodiode; and
a second sub-pixel surface grating disposed at a surface of the second sub-pixel photodiode, a configuration of the first sub-pixel surface grating being different from a configuration of the second sub-pixel surface grating.

13. The semiconductor device structure of claim 12, wherein:
the first sub-pixel surface grating has a first periodicity that is along a direction parallel to a first lateral direction across the semiconductor substrate and that is equal to or less than half of a dimension of the first sub-pixel photodiode parallel to the first lateral direction, the first periodicity having a first period including a first pitch;
the second sub-pixel surface grating has a second periodicity that is along a direction parallel to the first lateral direction and that is equal to or less than half of a dimension of the second sub-pixel photodiode parallel to the first lateral direction, the second periodicity having a second period including a second pitch; and
the first pitch is different from the second pitch.

14. The semiconductor device structure of claim 13, wherein:
the first period is equal to a length of the first pitch; and
the second period is equal to a length of the second pitch.

15. The semiconductor device structure of claim 13, wherein:
the first sub-pixel surface grating has a third periodicity that is along a direction parallel to a second lateral direction across the semiconductor substrate, the second lateral direction being perpendicular to the first lateral direction, the third periodicity being the same as the first periodicity; and
the second sub-pixel surface grating has a fourth periodicity that is along a direction parallel to the second lateral direction, the fourth periodicity being the same as the second periodicity.

16. A method for semiconductor processing, the method comprising:
forming one or more photodiodes of a photodetector device, the one or more photodiodes being formed disposed in or over a semiconductor substrate; and
forming a surface grating disposed at a respective surface of each photodiode of the one or more photodiodes, the surface grating having one or more periodicities, each periodicity of the one or more periodicities having a period that is along a direction parallel to a lateral direction across the semiconductor substrate and that is equal to or less than half of a dimension of at least one photodiode of the one or more photodiodes along a direction parallel to the lateral direction, the one or more periodicities including multiple different pitches.

17. The method of claim 16, wherein:
the one or more periodicities include a first periodicity and a second periodicity;
the period of the first periodicity include a first pitch of the multiple different pitches; and
the period of the second periodicity includes a second pitch of the multiple different pitches, the second pitch being different from the first pitch.

18. The method of claim 16, wherein the period of a periodicity of the one or more periodicities includes the multiple different pitches.

19. The method of claim 16, wherein:
forming the one or more photodiodes includes:
forming a first sub-pixel photodiode disposed in or over the semiconductor substrate; and
forming a second sub-pixel photodiode disposed in or over the semiconductor substrate, the first sub-pixel photodiode and the second sub-pixel photodiode being electrically connected together in parallel in the photodetector device; and
forming the surface grating includes:
forming a first sub-pixel surface grating disposed at a surface of the first sub-pixel photodiode, the first sub-pixel surface grating having a first periodicity of the one or more periodicities, the period of the first periodicity being equal to a length of a first pitch of the multiple different pitches; and
forming a second sub-pixel surface grating disposed at a surface of the second sub-pixel photodiode, the second sub-pixel surface grating having a second periodicity of the one or more periodicities, the period of the second periodicity being equal to a length of a second pitch of the multiple different pitches, the first pitch and the second pitch being different.

20. The method of claim 16, wherein the surface grating includes an isolation region, a semiconductor surface region, a dummy gate structure, or a combination thereof.
